(19) United States
(12) Patent Application Publication
(10) Pub. No.: US 2025/0301827 A1
(43) Pub. Date: Sep. 25, 2025

(54) LIGHT-EMITTING DEVICE, LIGHT-EMITTING MODULE, AND METHOD FOR MANUFACTURING LIGHT-EMITTING DEVICE

(71) Applicant: NICHIA CORPORATION, Anan-shi (JP)

(72) Inventors: Tsuyoshi OKAHISA, Tokushima-shi (JP); Keiji OKIDA, Anan-shi (JP)

(73) Assignee: NICHIA CORPORATION, Anan-shi (JP)

(21) Appl. No.: 19/073,795

(22) Filed: Mar. 7, 2025

(30) Foreign Application Priority Data
Mar. 19, 2024 (JP) 2024-043905
Oct. 7, 2024 (JP) 2024-175955
Jan. 23, 2025 (JP) 2025-010097

(51) Int. Cl. H10H 20/813; H10H 20/01; H10H 20/831; H10H 20/854; H10H 20/855; H10H 29/20; H10H 29/853; H10H 29/854

(52) U.S. Cl. CPC H10H 20/8133; H10H 20/032; H10H 20/0361; H10H 20/0364; H10H 20/831; H10H 20/854; H10H 20/855; H10H 29/20; H10H 29/853; H10H 29/854

(57) ABSTRACT

A light-emitting device includes a light-emitting element having first to fourth outer edges and including: an inner light-emitting portion including an inner semiconductor structure and inner electrodes; and an outer light-emitting portion surrounding an entire periphery of the inner light-emitting portion in the plan view and including an outer semiconductor structure, a first outer electrode including first to fourth extending portion respectively extending along the first outer edge, one of the third and fourth outer edges, the second outer edge, and the other of the third and fourth outer edges. An outermost surface of the light-emitting element includes surfaces of the inner and outer semiconductor structures. In the plan view, a first gap is between end portions of the first and fourth extending portions, and a second gap is between end portions of the second and third extending portions.

### CROSS-REFERENCE TO RELATED APPLICATIONS

This application claims priority to Japanese Patent Application No. 2024-043905, filed on Mar. 19, 2024, Japanese Patent Application No. 2024-175955, filed on Oct. 7, 2024, and Patent Application No. 2025-010097, filed on Jan. 23, 2025. The disclosures of these applications are hereby incorporated by reference in their entireties.

### BACKGROUND

### Technical Field

The present disclosure relates to a light-emitting device, a light-emitting module, and a method for manufacturing a light-emitting device.

### Background Art

There is known a light-emitting device obtained by disposing an element substrate provided with a plurality of light-emitting portions on a support member and then removing the element substrate (for example, see Chinese Patent Application Publication No. 102117821.)

### SUMMARY

One object of the present disclosure is to provide a light-emitting device in which the areas of semiconductor structures and the areas of electrodes can be increased, a light-emitting module, and a method for manufacturing the light-emitting device.

According to one aspect of the present disclosure, a light-emitting device includes a light-emitting element disposed on the support member, the light-emitting element having a rectangular shape in a plan view and including a first outer edge and a second outer edge each extending in a first direction and a third outer edge and a fourth outer edge each extending in a second direction orthogonal to the first direction. The light-emitting element includes: an inner light-emitting portion including an inner semiconductor structure having an inner light-emitting surface and an inner electrode surface located on a side opposite the inner light-emitting surface, and positive and negative inner electrodes disposed on the inner electrode surface; and an outer light-emitting portion surrounding an entire periphery of the inner light-emitting portion in a plan view and including an outer semiconductor structure having an outer light-emitting surface and an outer electrode surface located on a side opposite the outer light-emitting surface, and positive and negative outer electrodes disposed on the outer electrode surface, the positive and negative outer electrodes including: a first outer electrode including a first extending portion extending along the first outer edge, and a second extending portion extending along one of the third outer edge and the fourth outer edge; and a second outer electrode including a third extending portion extending along the second outer edge, and a fourth extending portion extending along the other of the third outer edge and the fourth outer edge. An outermost surface of the light-emitting element being the light-emitting surface thereof includes the inner light-emitting surface of the inner semiconductor structure and the outer light-emitting surface of the outer semiconductor structure. In a plan view, a first gap is located between an end portion of the first extending portion and an end portion of the fourth extending portion, and a second gap is located between an end portion of the second extending portion and an end portion of the third extending portion.

According to one aspect of the present disclosure, a light-emitting device includes a support member; and a light-emitting element disposed on the support member, the light-emitting element having a rectangular shape in a plan view and including a first outer edge and a second outer edge each extending in a first direction and a third outer edge and a fourth outer edge each extending in a second direction orthogonal to the first direction in the plan view. The light-emitting element includes: an inner light-emitting portion including an inner semiconductor structure having an inner light-emitting surface and an inner electrode surface located on a side opposite the inner light-emitting surface, and positive and negative inner electrodes disposed on the inner electrode surface, the inner electrodes including: a first inner electrode that is continuous along the first outer edge, the second outer edge, the third outer edge, and the fourth outer edge, and a second inner electrode that is continuous along the first outer edge, the second outer edge, the third outer edge, and the fourth outer edge, and an outer light-emitting portion surrounding an entire periphery of the inner light-emitting portion in the plan view and including an outer semiconductor structure having an outer light-emitting surface and an outer electrode surface located on a side opposite the outer light-emitting surface and positive and negative outer electrodes disposed on the outer electrode surface, the outer electrodes including: a first outer electrode that is continuous along the first outer edge, the second outer edge, the third outer edge, and the fourth outer edge, and a second outer electrode that is continuous along the first outer edge, the second outer edge, the third outer edge, and the fourth outer edge. An outermost surface of the light-emitting element being the light-emitting surface thereof includes the inner light-emitting surface of the inner semiconductor structure and the outer light-emitting surface of the outer semiconductor structure. In the plan view, the first outer electrode and the first inner electrode are disposed between the second outer electrode and the second inner electrode. The support member includes a common wiring portion bonded in common to the first outer electrode and the first inner electrode.

According to one aspect of the present disclosure, a light-emitting module includes the light-emitting device described above in which the inner light-emitting portion includes a central light-emitting portion having a rectangular shape, located at a center of the inner light-emitting portion, and configured to emit light to a central region in an irradiation region; and a lens disposed above the inner light-emitting surface and the outer light-emitting surface of the light-emitting device, in which an amount of change in a light distribution angle of the central light-emitting portion caused by the lens is larger than an amount of change in a light distribution angle of the outer light-emitting portion caused by the lens.

According to one aspect of the present disclosure, a method for manufacturing a light-emitting device includes providing a structure including an element substrate having a first surface and a second surface located at a side opposite the first surface, and a light-emitting element disposed on the second surface of the element substrate, the light-emitting element having a rectangular shape in a plan view and including, in the plan view, a first outer edge and a second outer edge each extending in a first direction and a third outer edge and a fourth outer edge each extending in a second direction orthogonal to the first direction, disposing the structure on a support member such that the second surface of the element substrate faces the support member; and separating the element substrate from the light-emitting element after the disposing of the structure on the support member. The light-emitting element includes: an inner light-emitting portion including an inner semiconductor structure having an inner light-emitting surface and an inner electrode surface located at a side opposite the inner light-emitting surface, and positive and negative inner electrodes disposed on the inner electrode surface; and an outer light-emitting portion surrounding an entire periphery of the inner light-emitting portion in the plan view and including an outer semiconductor structure having an outer light-emitting surface and an outer electrode surface located at a side opposite the outer light-emitting surface, and positive and negative outer electrodes disposed on the outer electrode surface. The outer electrodes include: a first outer electrode including a first extending portion extending along the first outer edge and a second extending portion extending along one of the third outer edge and the fourth outer edge; and a second outer electrode including a third extending portion extending along the second outer edge and a fourth extending portion extending along the other of the third outer edge and the fourth outer edge.

According to certain embodiments of the present disclosure, a light-emitting device in which an area of a semiconductor structure and an area of an electrode can be increased, a light-emitting module, and a method for manufacturing the light-emitting device can be provided.

### BRIEF DESCRIPTION OF DRAWINGS

FIG. 1 is a schematic plan view of a light-emitting device according to a first embodiment.

FIG. 2 is a schematic cross-sectional view taken along line II-II in FIG. 1.

FIG. 3 is a schematic plan view of a light-emitting element in the light-emitting device according to the first embodiment.

FIG. 4 is a schematic plan view of a support member in the light-emitting device according to the first embodiment.

FIG. 5 is a schematic plan view of the support member in the light-emitting device according to the first embodiment.

FIG. 6 is a schematic plan view of the light-emitting element in the light-emitting device according to the first embodiment.

FIG. 7 is a schematic plan view of the light-emitting device according to the first embodiment.

FIG. 8 is a schematic plan view of the light-emitting device according to the first embodiment.

FIG. 9 is a schematic plan view of the light-emitting device according to the first embodiment.

FIG. 10 is a schematic plan view of a light-emitting element in a light-emitting device according to a second embodiment.

FIG. 11 is a schematic cross-sectional view of the light-emitting device according to the second embodiment.

FIG. 12 is a schematic plan view of a support member in the light-emitting device according to the second embodiment.

FIG. 13 is a schematic cross-sectional view of a light-emitting module according to one embodiment.

FIG. 14A is a schematic cross-sectional view of a light-emitting module according to a first modified example.

FIG. 14B is a schematic cross-sectional view of a light-emitting module according to a second modified example.

FIG. 14C is a schematic cross-sectional view of a light-emitting module according to a third modified example.

FIG. 14D is a schematic plan view of a light-emitting module according to a fourth modified example.

FIG. 14E is a schematic cross-sectional view of the light-emitting module taken along line XIVE-XIVE of FIG. 14D.

FIG. 14F is a schematic plan view of a light-emitting module according to a fourth modified example.

FIG. 14G is a schematic cross-sectional view of the light-emitting module taken along line XIVG-XIVG of FIG. 14F.

FIG. 15A is a schematic cross-sectional view for explaining a step of a method for manufacturing the light-emitting device according to the first embodiment.

FIG. 15B is a schematic cross-sectional view for explaining a step of the method for manufacturing the light-emitting device according to the first embodiment.

FIG. 15C is a schematic cross-sectional view for explaining a step of the method for manufacturing the light-emitting device according to the first embodiment.

FIG. 15D is a schematic cross-sectional view for explaining a step of the method for manufacturing the light-emitting device according to the first embodiment.

FIG. 15E is a schematic plan view for explaining a step of the method for manufacturing the light-emitting device according to the first embodiment.

FIG. 15F is a schematic plan view for explaining a step of the method for manufacturing the light-emitting device according to the first embodiment.

FIG. 15G is a schematic plan view for explaining a step of the method for manufacturing the light-emitting device according to the first embodiment.

FIG. 15H is a schematic plan view for explaining a step of the method for manufacturing the light-emitting device according to the first embodiment.

FIG. 15I is a schematic cross-sectional view for explaining a step of the method for manufacturing the light-emitting device according to the first embodiment.

FIG. 15J is a schematic cross-sectional view for explaining a step of the method for manufacturing the light-emitting device according to the first embodiment.

FIG. 16A is a schematic cross-sectional view for explaining a step of a method for manufacturing the light-emitting device according to the second embodiment.

FIG. 16B is a schematic cross-sectional view for explaining a step of the method for manufacturing the light-emitting device according to the second embodiment.

FIG. 16C is a schematic cross-sectional view for explaining a step of the method for manufacturing the light-emitting device according to the second embodiment.

FIG. 16D is a schematic cross-sectional view for explaining a step of the method for manufacturing the light-emitting device according to the second embodiment.

FIG. 16E is a schematic cross-sectional view for explaining a step of the method for manufacturing the light-emitting device according to the second embodiment.

### DETAILED DESCRIPTION

Embodiments of the present disclosure are described below with reference to the drawings. The following embodiments are examples for embodying the technical concept of the present disclosure, and are not limited to the following. Further, dimensions, materials, shapes, relative arrangements, or the like of constituent members described in the embodiments are not intended to limit the scope of the present disclosure thereto, unless otherwise specified, and are merely exemplary. Note that the size, positional relationship, or the like of members illustrated in each of the drawings may be exaggerated for clarity of description. Further, in the following description, members having the same terms and reference characters represent the same members or members of the same quality, and a detailed description of these members will be omitted as appropriate. As a cross-sectional view, an end view illustrating only a cut surface may be illustrated.

In the following description, terms indicating specific directions or positions (e.g., “upper,” “above,” “lower,” “below,” and other terms including those terms) may be used. However, these terms are used merely to make it easy to understand relative directions or positions in the referenced drawing. As long as the relative direction or position is the same as that described in the referenced drawing using the term such as “upper” or “lower,” in drawings other than the drawings of the present disclosure, actual products, and the like, components need not be arranged in the same manner as that in the referenced drawing. Further, assuming that there are two members, the positional relationship expressed as “upper or above (or lower or below)” in the present specification may include a case in which the two members are in contact with each other and a case in which the two members are not in contact with each other and one of the two members is located above (or below) the other member. Further, in the present specification, unless otherwise specified, a case in which a member covers an object to be covered includes a case in which the member is in contact with the object to be covered and directly covers the object to be covered, and a case in which the member is not in contact with the object to be covered and indirectly covers the object to be covered. Further, in the present specification, a width, a distance, and a thickness of a member in a specific direction respectively represent maximum values of the width, the distance, and the thickness in the specific direction. Further, the term “a plan view” used in the embodiments below refers to viewing an object from above. Note that in the present specification, in addition to a portion that is directly visible from above, a portion that is not directly visible from above may also be described as if it is seen through, using the term “plan view.”

In the following drawings, directions may be indicated by an X axis, a Y axis, and a Z axis. A direction along the X-axis (for example, referred to as a first direction X) indicates a predetermined direction in a light-emitting surface of a light-emitting device according to an embodiment. A direction along the Y-axis (for example, referred to as a second direction Y) indicates a direction orthogonal to the first direction X in the light-emitting surface. The light-emitting surface of the light-emitting device is parallel to an XY plane. A direction along the Z-axis (for example, referred to as a third direction Z) indicates a direction orthogonal to the light-emitting surface of the light-emitting device.

### Light-Emitting Device According to First Embodiment

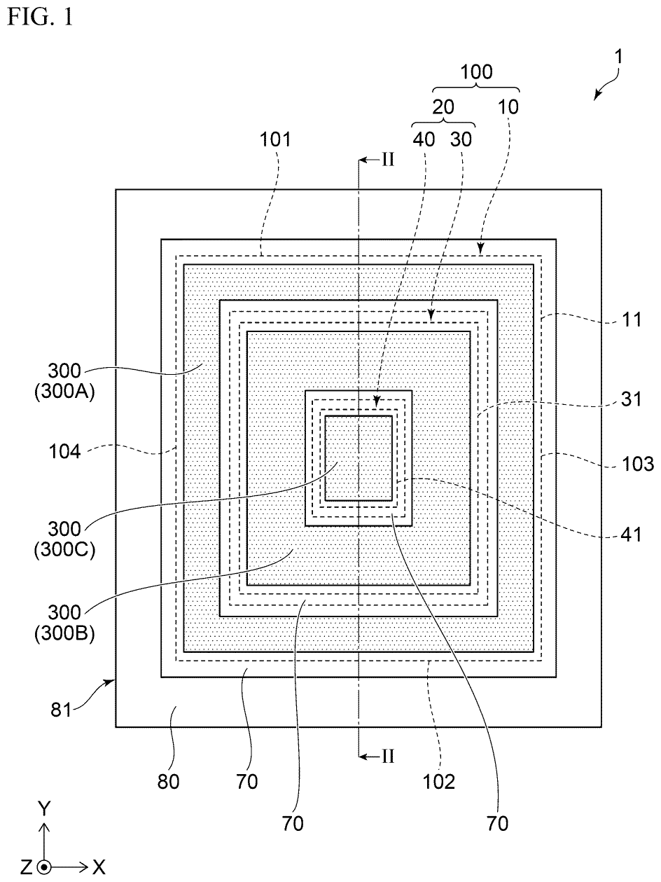

A light-emitting device 1 according to a first embodiment will be described below with reference to FIGS. 1 to 9.

The light-emitting device 1 according to the first embodiment includes a support member 200 and a light-emitting element 100 disposed on the support member 200.

### Light-Emitting Element

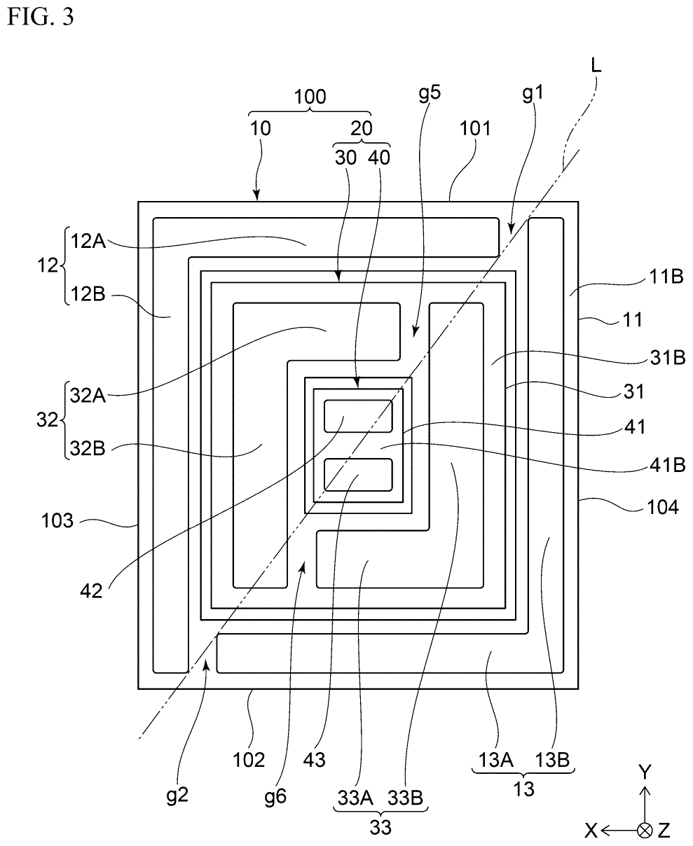

As illustrated in FIGS. 1 and 3, in a plan view, an outer edges of the light-emitting element 100 form a rectangular shape having a first outer edge 101 and a second outer edge 102 extending in the first direction X, and a third outer edge 103 and a fourth outer edge 104 extending in the second direction Y. FIG. 1 is a plan view of the light-emitting element 100 showing a light-emitting surface side of the light-emitting element 100. FIG. 3 is a plan view of the light-emitting element 100 showing a side of a surface opposite to the light-emitting surface. In the present embodiment, the light-emitting surface of the light-emitting element 100 refers to a main light extraction surface.

The light-emitting element 100 includes an inner light-emitting portion 20 and an outer light-emitting portion 10 surrounding the entire periphery of the inner light-emitting portion 20 in a plan view.

### Outer Light-Emitting Portion

The outer light-emitting portion 10 includes an outer semiconductor structure 11 and positive and negative outer electrodes 12 and 13. When a current is supplied to the outer semiconductor structure 11 through the positive and negative outer electrodes 12 and 13, the outer semiconductor structure 11 emits light.

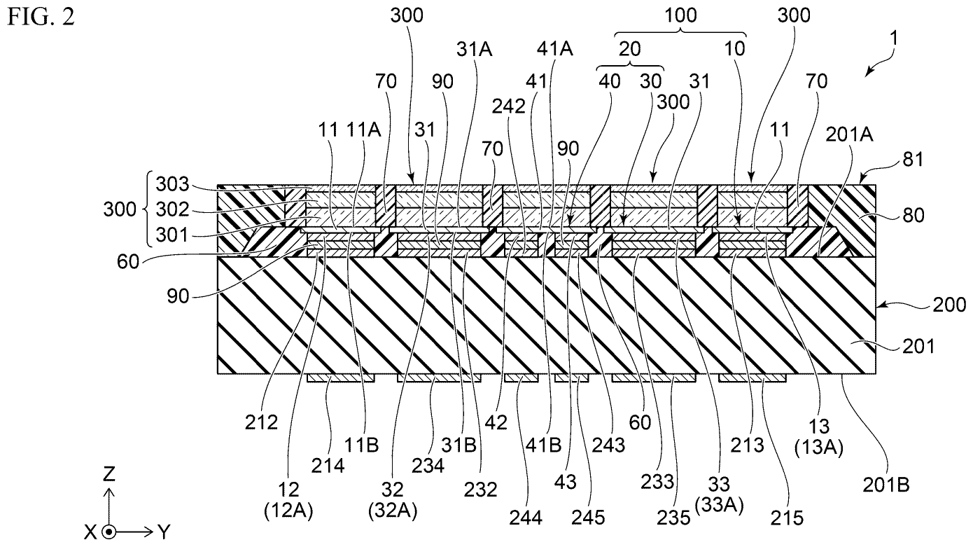

As illustrated in FIG. 2, the outer semiconductor structure 11 has an outer light-emitting surface 11A and an outer electrode surface 11B opposite to the outer light-emitting surface 11A in the third direction Z. As illustrated in FIG. 3, in a plan view, the outer edges of the outer semiconductor structure 11 constitute the first outer edge 101, the second outer edge 102, the third outer edge 103, and the fourth outer edge 104 of the light-emitting element 100. The outer semiconductor structure 11 is provided in a frame shape along the first outer edge 101, the second outer edge 102, the third outer edge 103, and the fourth outer edge 104 of the light-emitting element 100 in a plan view. The outer light-emitting surface 11A has a rectangular annular shape along the first outer edge 101, the second outer edge 102, the third outer edge 103, and the fourth outer edge 104. For example, when a plurality of semiconductor structures are spaced apart from each other and disposed along the outer edges of the light-emitting element, no light-emitting surface exists between the semiconductor structures. In comparison with this configuration, in the present embodiment, since the outer semiconductor structure 11 has a continuous frame shape, the area of the outer light-emitting surface 11A of the outer semiconductor structure 11 can be increased, so that the light output of the outer light-emitting portion 10 can be improved.

As illustrated in FIG. 3, the outer electrodes 12 and 13 are disposed on the outer electrode surface 11B of the outer semiconductor structure 11. The outer electrodes include a first outer electrode 12 and a second outer electrode 13. For example, the first outer electrode 12 is a cathode electrode of the outer light-emitting portion 10, and the second outer electrode 13 is an anode electrode of the outer light-emitting portion 10. The number of the outer electrodes 12 and 13 is not limited to two, and may be three or more. As the material of the outer electrodes, for example, Ti, Pt, or Au can be used.

The first outer electrode 12 includes a first extending portion 12A extending along the first outer edge 101 and a second extending portion 12B extending along one of the third outer edge 103 and the fourth outer edge 104. The second outer electrode 13 includes a third extending portion 13A extending along the second outer edge 102 and a fourth extending portion 13B extending along the other of the third outer edge 103 and the fourth outer edge 104. In the present embodiment, the first outer electrode 12 includes the first extending portion 12A extending along the first outer edge 101 and the second extending portion 12B extending along the third outer edge 103. The second outer electrode 13 includes the third extending portion 13A extending along the second outer edge 102 and the fourth extending portion 13B extending along the fourth outer edge 104.

The first extending portion 12A and the second extending portion 12B of the first outer electrode 12 are continuous with each other, and the third extending portion 13A and the fourth extending portion 13B of the second outer electrode 13 are continuous with each other. In the example illustrated in FIG. 3, the first extending portion 12A and the second extending portion 12B are continuous with each other via a corner portion, e.g., to form an L shape. The third extending portion 13A and the fourth extending portion 13B are continuous with each other via a corner portion, e.g., to form an L shape. A length in the first direction X of each of the first extending portion 12A and the third extending portion 13A is, for example, in a range of 1000 μm to 4000 μm. A length in the second direction Y of each of the first extending portion 12A and the third extending portion 13A is, for example, in a range of 50 μm to 300 μm. A length in the first direction X of each of the second extending portion 12B and the fourth extending portion 13B is, for example, in a range of 50 μm to 300 μm. A length in the second direction Y of each of the second extending portion 12B and the fourth extending portion 13B is, for example, in a range of 1300 μm to 5200 μm. The length of each of the first extending portion 12A, the second extending portion 12B, the third extending portion 13A, and the fourth extending portion 13B refers to the length of outer edges that are adjacent to each other along corresponding two of the first outer edge 101, the second outer edge 102, the third outer edge 103, and the fourth outer edge 104 and are farther from the center of the light-emitting element 100 in a plan view, in a corresponding one of the extending portions.

As long as the first outer electrode 12 and the second outer electrode 13 are bonded and electrically connected to the support member 200, the first outer electrode 12 and the second outer electrode 13 may have a shape in which corner portions are chamfered in a plan view.

In a plan view, a first gap g1 is located between an end portion of the first extending portion 12A and an end portion of the fourth extending portion 13B, and a second gap g2 is located between an end portion of the second extending portion 12B and an end portion of the third extending portion 13A. Each of the first gap g1 and the second gap g2 separate the positive and negative outer electrodes (the anode electrode and the cathode electrode) from each other on the outer electrode surface 11B of the outer semiconductor structure 11.

In a plan view, the end portion of the first extending portion 12A and the end portion of the fourth extending portion 13B are spaced apart from each other in the first direction X with the first gap g1 located therebetween. Alternatively, the end portion of the first extending portion 12A and the end portion of the fourth extending portion 13B may be spaced apart from each other in the second direction Y with the first gap g1 located therebetween. The width of the first gap g1 along the first direction X or the second direction Y is, for example, in a range from 50 μm to 300 μm. In the present embodiment, as the width of the first gap g1 in the first direction X approaches 50 μm, the planar areas of the outer electrodes can be increased, and higher heat dissipation can be exhibited. In addition, as the width of the first gap g1 in the first direction X approaches 300 μm, the resistance to migration is improved, and the migration can be reduced even in high voltage driving. Even when the end portion of the first extending portion 12A and the end portion of the fourth extending portion 13B are spaced apart from each other in a range from 50 μm to 300 μm in the second direction Y with the first gap g1 located therebetween, the same effect as that described above can be exhibited.

In a plan view, the end portion of the second extending portion 12B and the end portion of the third extending portion 13A are spaced apart from each other in the first direction X with the second gap g2 located therebetween. Alternatively, the end portion of the second extending portion 12B and the end portion of the third extending portion 13A may be spaced apart from each other in the second direction Y with the second gap g2 located therebetween. The width of the second gap g2 along the first direction X or the second direction Y is, for example, in a range of 50 μm to 300 μm. In the present embodiment, as the width of the second gap g2 in the first direction X approaches 50 μm, the planar areas of the outer electrodes can be increased, and higher heat dissipation is obtained. In addition, as the width of the second gap g2 in the first direction X approaches 300 μm, the resistance to migration is improved, and the migration can be reduced even in high voltage driving. Even when the end portion of the second extending portion 12B and the end portion of the third extending portion 13A are spaced apart from each other in a range of 50 μm to 300 μm in the second direction Y with the second gap g2 located therebetween, the same effect as that described above can be exhibited.

The outer semiconductor structure 11 is has a frame shape along the first outer edge 101, the second outer edge 102, the third outer edge 103, and the fourth outer edge 104 of the light-emitting element 100 in a plan view, and the outer electrode surface 11B is disposed along the first outer edge 101, the second outer edge 102, the third outer edge 103, and the fourth outer edge 104. Thus, the outer electrodes 12 and 13 are extended along the first outer edge 101, the second outer edge 102, the third outer edge 103, and the fourth outer edge 104, so that the areas of the outer electrodes 12 and 13 can be increased. Heat generated by light emission of the outer semiconductor structure 11 is dissipated to the support member 200 through the outer electrodes 12 and 13. Increase in the areas of the outer electrodes 12 and 13 allows for enhancing the dissipation of heat generated by the outer semiconductor structure 11.

The length of the first extending portion 12A in the first direction X is preferably ¾ or more, more preferably ⅘ or more of the length of the first outer edge 101. The length of the second extending portion 12B in the second direction Y is preferably ⅘ or more, more preferably 9/10 or more of the length of the third outer edge 103. The length of the third extending portion 13A in the first direction X is preferably ¾ or more, more preferably ⅘ or more of the length of the second outer edge 102. The length of the fourth extending portion 13B in the second direction Y is preferably ⅘ or more, more preferably 9/10 or more of the length of the fourth outer edge 104.

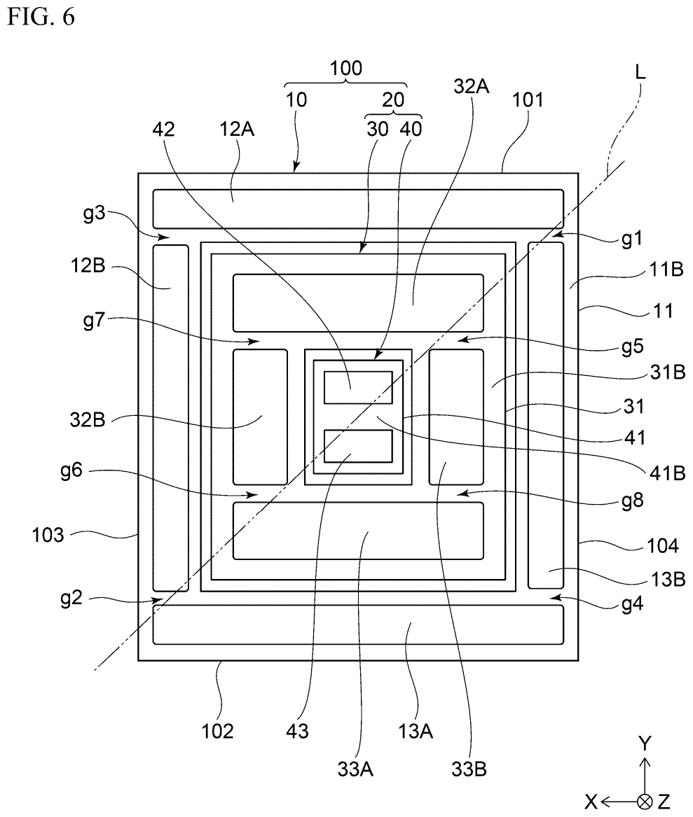

In the first outer electrode 12 and the second outer electrode 13, a third gap g3 may be located between the end portion of the first extending portion 12A and the end portion of the second extending portion 12B in a plan view as in the modified example illustrated in FIG. 6. In a plan view, a fourth gap g4 may be located between the end portion of the third extending portion 13A and the end portion of the fourth extending portion 13B. For example, in a plan view, the end portion of the first extending portion 12A and the end portion of the second extending portion 12B are spaced apart from each other in the second direction Y with the third gap g3 located therebetween. The end portion of the third extending portion 13A and the end portion of the fourth extending portion 13B are spaced apart from each other in the second direction Y with the fourth gap g4 located therebetween. Alternatively, in a plan view, the end portion of the first extending portion 12A and the end portion of the second extending portion 12B may be spaced apart from each other in the first direction X with the third gap g3 located therebetween. In addition, the end portion of the third extending portion 13A and the end portion of the fourth extending portion 13B may be spaced apart from each other in the first direction X with the fourth gap g4 located therebetween.

The ratio L2/L1 of a total length L2 in the direction along the first outer edge 101, the second outer edge 102, the third outer edge 103, and the fourth outer edge 104 of the outer electrodes 12 and 13 to a total length L1 in the direction along the first outer edge 101, the second outer edge 102, the third outer edge 103, and the fourth outer edge 104 of the outer electrode surface 11B of the outer semiconductor structure 11 is preferably 0.8 or more. Moreover, L2/L1 is more preferably 0.9 or more. With such a length ratio, the areas of the outer electrodes 12 and 13 on the outer electrode surface 11B are easily increased. L1 represents the total length of center lines, through the centers in the second direction Y, of the two extending portions extending in the first direction X of the outer electrode surface 11B of the outer semiconductor structure 11 and center lines, through the centers in the first direction X, of the two extending portions extending in the second direction Y of the outer electrode surface 11B. L2 represents the total length of a center line of the first extending portion 12A through the center in the second direction Y of the first extending portion 12A, a center line of the second extending portion 12B through the center in the first direction X of the second extending portion 12B, a center line of the third extending portion 13A through the center in the second direction Y of the third extending portion 13A, and a center line of the fourth extending portion 13B through the center in the first direction X of the fourth extending portion 13B.

In the configuration illustrated in FIG. 3, L1 can be 8.15 mm, and the widths of the first gap g1 and the second gap g2 in the first direction X can be 0.15 mm. In the configuration illustrated in FIGS. 3, L2=8.15−(0.15×2)=7.85 mm. The ratio L2/L1 is 0.963.

In the configuration illustrated in FIG. 6, L1 can be 8.15 mm, and the width in the second direction Y of each of the first gap g1, the second gap g2, the third gap g3, and the fourth gap g4 can be 0.15 mm. In the configuration illustrated in FIGS. 6, L2=8.15−(0.15×4)=7.55 mm. The ratio L2/L1 is 0.926.

When the lengths L1 of the outer electrode surfaces 11B are the same, the ratio L2/L1 can be higher and the areas of the outer electrodes 12 and 13 can be larger in the configuration illustrated in FIG. 3 in which the gap between the extending portions of the outer electrodes is smaller than in the configuration illustrated in FIG. 6.

### Inner Light-Emitting Portion

The inner light-emitting portion 20 includes at least one of a frame-shaped light-emitting portion along the first outer edge 101, the second outer edge 102, the third outer edge 103, and the fourth outer edge 104, and a rectangular central light-emitting portion located at the center of the inner light-emitting portion 20 in a plan view. In the present embodiment, the inner light-emitting portion 20 includes a frame-shaped inner light-emitting portion 30 and a central light-emitting portion 40. The frame-shaped inner light-emitting portion 30 is an example of a frame-shaped light-emitting portion. The inner light-emitting portion 20 is not limited to including both the frame-shaped inner light-emitting portion 30 and the central light-emitting portion 40. In one example, the inner light-emitting portion 20 includes either the frame-shaped inner light-emitting portion 30 or the central light-emitting portion 40. The inner light-emitting portion 20 is not limited to including one frame-shaped inner light-emitting portion 30, and may include two or more frame-shaped light-emitting portions.

In a plan view, when a plurality of light-emitting portions are provided, a light-emitting portion disposed on the outermost side may be defined as an outer light-emitting portion, and one or more light-emitting portions disposed inside the outer light-emitting portion may be defined as inner light-emitting portions.

### Frame-Shaped Inner Light-Emitting Portion

In a plan view, the frame-shaped inner light-emitting portion 30 surrounds the entire periphery of the central light-emitting portion 40 and is located between the outer light-emitting portion 10 and the central light-emitting portion 40. The frame-shaped inner light-emitting portion 30 is spaced apart from the outer light-emitting portion 10 and the central light-emitting portion 40 in the first direction X. The frame-shaped inner light-emitting portion 30 is spaced apart from the outer light-emitting portion 10 and the central light-emitting portion 40 in the second direction Y. A separation distance between the frame-shaped inner light-emitting portion 30 and the outer light-emitting portion 10 in the first direction X, a separation distance between the frame-shaped inner light-emitting portion 30 and the central light-emitting portion 40 in the first direction X, a separation distance between the frame-shaped inner light-emitting portion 30 and the outer light-emitting portion 10 in the second direction Y, and a separation distance between the frame-shaped inner light-emitting portion 30 and the central light-emitting portion 40 in the second direction Y are each, for example, in a range of 1 μm to 30 μm.

The frame-shaped inner light-emitting portion 30 includes a frame-shaped inner semiconductor structure 31 and positive and negative inner electrodes 32 and 33. A current is supplied to the frame-shaped inner semiconductor structure 31 through the positive and negative inner electrodes 32 and 33, so that the frame-shaped inner semiconductor structure 31 emits light.

As illustrated in FIG. 2, the frame-shaped inner semiconductor structure 31 has a frame-shaped inner light-emitting surface 31A and a frame-shaped inner electrode surface 31B opposite to the frame-shaped inner light-emitting surface 31A in the third direction Z. As illustrated in FIG. 3, in a plan view, the frame-shaped inner semiconductor structure 31 has a rectangular annular shape along the first outer edge 101, the second outer edge 102, the third outer edge 103, and the fourth outer edge 104 of the light-emitting element 100. The frame-shaped inner light-emitting surface 31A has a rectangular annular shape along the first outer edge 101, the second outer edge 102, the third outer edge 103, and the fourth outer edge 104. For example, if a plurality of semiconductor structures are arranged to be spaced apart from each other along the outer edges of the light-emitting element, no light-emitting surface exists between the semiconductor structures. In comparison with this configuration, in the present embodiment, the frame-shaped inner semiconductor structure 31 has a continuous frame shape, so that the area of the frame-shaped inner light-emitting surface 31A of the frame-shaped inner semiconductor structure 31 can be increased, which allows for improving the light output of the frame-shaped inner light-emitting portion 30.

The inner electrodes 32 and 33 are disposed on the frame-shaped inner electrode surface 31B of the frame-shaped inner semiconductor structure 31. The inner electrodes include the first inner electrode 32 and the second inner electrode 33. For example, the first inner electrode 32 is a cathode electrode in the frame-shaped inner light-emitting portion 30, and the second inner electrode 33 is an anode electrode in the frame-shaped inner light-emitting portion 30. The number of the inner electrodes 32 and 33 is not limited to two, and may be three or more. As the material of the inner electrodes, for example, Ti, Pt, or Au can be used.

The first inner electrode 32 includes a fifth extending portion 32A extending along the first extending portion 12A of the first outer electrode 12 and a sixth extending portion 32B extending along the second extending portion 12B of the first outer electrode 12. The second inner electrode 33 includes a seventh extending portion 33A extending along the third extending portion 13A of the second outer electrode 13 and an eighth extending portion 33B extending along the fourth extending portion 13B of the second outer electrode 13. The fifth extending portion 32A and the sixth extending portion 32B are continuous with each other via a corner portion, e.g., to have an L shape. The seventh extending portion 33A and the eighth extending portion 33B are continuous with each other via a corner portion, e.g., to have an L shape. A length in the first direction X of each of the fifth extending portion 32A and the seventh extending portion 33A is, for example, in a range of 500 μm to 3000 μm. A length in the second direction Y of each of the fifth extending portion 32A and the seventh extending portion 33A is, for example, in a range of 50 μm to 300 μm. A length in the first direction X of each of the sixth extending portion 32B and the eighth extending portion 33B is, for example, in a range of 50 μm to 300 μm. A length in the second direction Y of each of the sixth extending portion 32B and the eighth extending portion 33B is, for example, in a range of 650 μm to 3900 μm. The length of each of the fifth extending portion 32A, the sixth extending portion 32B, the seventh extending portion 33A, and the eighth extending portion 33B refer to the length of outer edges that are along corresponding two of the first outer edge 101, the second outer edge 102, the third outer edge 103, and the fourth outer edge 104 and are farther from the center of the light-emitting element 100 in a plan view in a corresponding one of the extending portions. In addition, in the present embodiment, the length of each of the fifth extending portion 32A, the sixth extending portion 32B, the seventh extending portion 33A, and the eighth extending portion 33B can also be regarded as referring to the length of outer edges that are adjacent to each other along corresponding two of the first extending portion 12A, the second extending portion 12B, the third extending portion 13A, and the fourth extending portion 13B and are farther from the center of the light-emitting element 100 in a plan view in a corresponding one of the extending portions.

As long as the first inner electrode 32 and the second inner electrode 33 are bonded and electrically connected to the support member 200, each of the first inner electrode 32 and the second inner electrode 33 may have a shape in which corner portions are chamfered in a plan view.

In a plan view, a fifth gap g5 is located between the end portion of the fifth extending portion 32A and the end portion of the eighth extending portion 33B, and a sixth gap g6 is located between the end portion of the sixth extending portion 32B and the end portion of the seventh extending portion 33A. The fifth gap g5 and the sixth gap g6 separate the positive and negative inner electrodes (the anode electrode and the cathode electrode) from each other on the frame-shaped inner electrode surface 31B of the frame-shaped inner semiconductor structure 31.

In a plan view, the end portion of the fifth extending portion 32A and the end portion of the eighth extending portion 33B are spaced apart from each other in the first direction X with the fifth gap g5 located therebetween. Alternatively, the end portion of the fifth extending portion 32A and the end portion of the eighth extending portion 33B may be spaced apart from each other in the second direction Y with the fifth gap g5 located therebetween. The width of the fifth gap g5 along the first direction X or the second direction Y is, for example, in a range of 50 μm to 300 μm. In the present embodiment, as the width of the fifth gap g5 in the first direction X approaches 50 μm, the planar areas of the outer electrodes can be increased, and higher heat dissipation is obtained. In addition, as the width of the fifth gap g5 in the first direction X approaches 300 μm, the resistance to migration is improved, and the migration can be reduced even in high voltage driving. Even when the end portion of the fifth extending portion 32A and the end portion of the eighth extending portion 33B are spaced apart from each other in a range from 50 μm to 300 μm in the second direction Y with the fifth gap g5 located therebetween, the same effect as described above is achieved.

In a plan view, the end portion of the sixth extending portion 32B and the end portion of the seventh extending portion 33A are spaced apart from each other in the first direction X with the sixth gap g6 located therebetween. Alternatively, the end portion of the sixth extending portion 32B and the end portion of the seventh extending portion 33A may be spaced apart from each other in the second direction Y with the sixth gap g6 located therebetween. The width of the sixth gap g6 along the first direction X or the second direction Y is, for example, in a range of 50 μm to 300 μm. In the present embodiment, as the width of the sixth gap g6 in the first direction X approaches 50 μm, the planar areas of the outer electrodes can be increased, and higher heat dissipation can be obtained. In addition, as the width of the sixth gap g6 in the first direction X approaches 300 μm, the resistance to migration is improved, and the migration can be reduced even in high voltage driving. Even when the end portion of the sixth extending portion 32B and the end portion of the seventh extending portion 33A are spaced apart from each other in a range from 50 μm to 300 μm in the second direction Y with the sixth gap g6 located therebetween, the same effect as that described above can be achieved.

The frame-shaped inner electrode surface 31B of the frame-shaped inner semiconductor structure 31 has a frame shape along the first outer edge 101, the second outer edge 102, the third outer edge 103, and the fourth outer edge 104 of the light-emitting element 100. Accordingly, the inner electrodes 32 and 33 extends along the first outer edge 101, the second outer edge 102, the third outer edge 103, and the fourth outer edge 104, thereby increasing the area of the inner electrodes 32 and 33. Heat generated by light emission of the frame-shaped inner semiconductor structure 31 is dissipated to the support member 200 through the inner electrodes 32 and 33. Increase in the areas of the inner electrodes 32 and 33 allows for increase in the dissipation of heat generated by the frame-shaped inner semiconductor structure 31 can be enhanced.

For the first inner electrode 32 and the second inner electrode 33, a seventh gap g7 may be located between the end portion of the fifth extending portion 32A and the end portion of the sixth extending portion 32B, and an eighth gap g8 may be located between the end portion of the seventh extending portion 33A and the end portion of the eighth extending portion 33B in a plan view, as in a modified example illustrated in FIG. 6. For example, in a plan view, the end portion of the fifth extending portion 32A and the end portion of the sixth extending portion 32B are spaced apart from each other in the second direction Y with the seventh gap g7 located therebetween, and the end portion of the seventh extending portion 33A and the end portion of the eighth extending portion 33B are spaced apart from each other in the second direction Y with the eighth gap g8 located therebetween. Alternatively, in a plan view, the end portion of the fifth extending portion 32A and the end portion of the sixth extending portion 32B may be spaced apart from each other in the first direction X with the seventh gap g7 interposed therebetween, and the end portion of the seventh extending portion 33A and the end portion of the eighth extending portion 33B may be spaced apart from each other in the first direction X with the eighth gap g8 located therebetween.

### Central Light-Emitting Portion

In a plan view, the central light-emitting portion 40 has a rectangular shape. The central light-emitting portion 40 includes a central inner semiconductor structure 41 and positive and negative inner electrodes 42 and 43. A current is supplied to the central inner semiconductor structure 41 through the positive and negative inner electrodes 42 and 43, so that the central inner semiconductor structure 41 emits light.

As illustrated in FIG. 2, the central inner semiconductor structure 41 includes a central inner light-emitting surface 41A and a central inner electrode surface 41B opposite to the central inner light-emitting surface 41A in the third direction Z.

The inner electrodes 42 and 43 are disposed on the central inner electrode surface 41B of the central inner semiconductor structure 41. The inner electrodes include the third inner electrode 42 and the fourth inner electrode 43. For example, the third inner electrode 42 is a cathode electrode in the central light-emitting portion 40, and the fourth inner electrode 43 is an anode electrode in the central light-emitting portion 40. The third inner electrode 42 and the fourth inner electrode 43 are spaced apart from each other in the second direction Y, for example. The third inner electrode 42 and the fourth inner electrode 43 may be spaced apart from each other in the first direction X. The inner electrodes may include three or more electrodes.

In the present embodiment, the positive and negative outer electrodes 12 and 13 and the positive and negative inner electrodes 32, 33, 42, and 43 are disposed so as to be rotationally symmetric about the center of the light-emitting element 100 as a central axis in a plan view. For example, as illustrated in FIG. 3, in a plan view, the positive and negative inner electrodes 32, 33, 42, and 43 are located on a virtual line L connecting the first gap g1 and the second gap g2. The positive and negative inner electrodes 32, 33, 42, and 43 need not be located on the virtual line L connecting the first gap g1 and the second gap g2.

For the outer electrode and the inner electrode, the number and positions of the gaps are not limited to the examples illustrated in FIGS. 3 and 6. For two or more gaps, the distance between the gaps is not limited to the examples illustrated in FIGS. 3 and 6. The number and positions of the gaps and the distance between the gaps may be appropriately adjusted in consideration of the heat dissipation and the like.

An outermost surface of the light-emitting element 100A being the light-emitting surface thereof includes an outer light-emitting surface of the outer semiconductor structure 11 and inner light-emitting surfaces of the inner semiconductor structures (the frame-shaped inner semiconductor structure 31 and the central inner semiconductor structure 41). An element substrate used for growing the semiconductor structures is not disposed on the outer light-emitting surface 11A of the outer semiconductor structure 11 and on the inner light-emitting surfaces (the frame-shaped inner light-emitting surface 31A and the central inner light-emitting surface 41A) of the inner semiconductor structures. Accordingly, in the light-emitting device 1 of the present embodiment, no absorption loss of light occurs in the element substrate.

Each of the outer light-emitting surface 11A of the outer semiconductor structure 11 and the inner light-emitting surfaces of the inner semiconductor structures includes a rough surface portion. The arithmetic mean roughness of the rough surface portion is, for example, in a range of 0.5 μm to 10 μm. The presence of the rough surface portion can improve the efficiency of extraction of light from the light-emitting surface of the light-emitting element 100. The outer semiconductor structure 11 or the inner semiconductor structures (the frame-shaped inner semiconductor structure 31 and the central inner semiconductor structure 41) may further include a protective film that protects the light-emitting surface of the light-emitting element 100. The outer light-emitting surface 11A of the outer semiconductor structure 11 and the inner light-emitting surfaces of the inner semiconductor structures may have no rough surface portion.

In the outer semiconductor structure 11 and the inner semiconductor structures (the frame-shaped inner semiconductor structure 31 and the central inner semiconductor structure 41), the thicknesses of the semiconductor structures in the third direction Z are, for example, in a range of 5 μm to 100 μm. As the thicknesses of the semiconductor structures in the third direction Z decrease, propagation of light inside the semiconductor structures decreases. Therefore, the thicknesses of the semiconductor structures in the third direction Z are preferably in a range of 5 μm to 20 μm. The semiconductor structures include a nitride semiconductor. Examples of the nitride semiconductor include any semiconductor having compositions of a chemical formula expressed by InₓAl_{y}Ga_{1-x-y}N (0≤x≤1, 0≤y≤1, x+y≤1) in which the composition ratios of x and y are varied within the respective ranges. Further, examples of the nitride semiconductor also include a semiconductor further containing a group V element other than nitrogen (N) in the chemical formula described above, and a semiconductor further containing, in the chemical formula described above, any of various elements added to control various physical properties such as the conductivity type of the semiconductor. Each of the semiconductor structures includes an active layer. The active layer is a light-emitting layer that emits light and has a multiple quantum well (MQW) structure including a plurality of barrier layers and a plurality of well layers, for example. Light emitted by the active layer is visible light or ultraviolet light, for example.

### Support Member

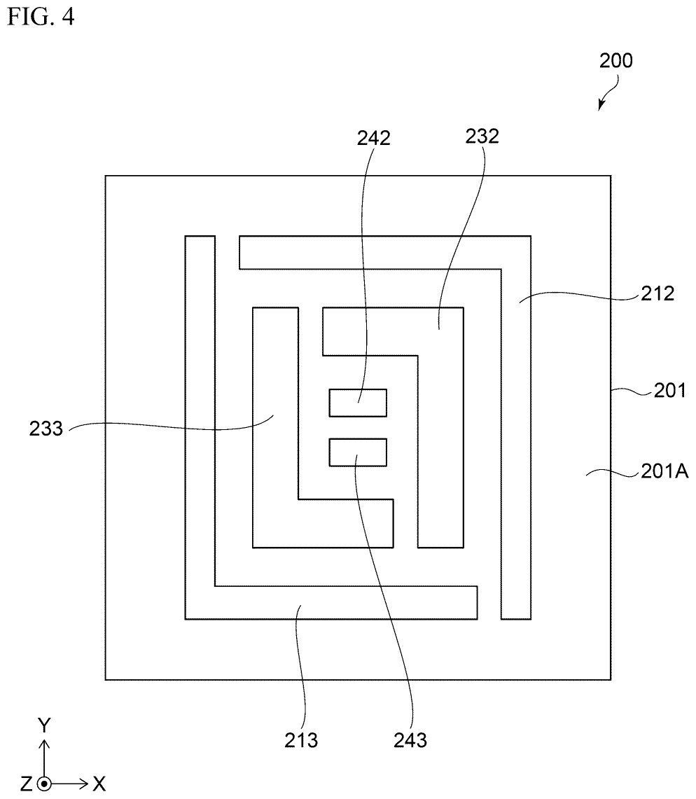

As illustrated in FIG. 2, the support member 200 includes an insulating base body 201 and a wiring portion. The support member 200 supports the light-emitting element 100 and serves as a wiring board that electrically connects the light-emitting element 100 to an external circuit. As illustrated in FIG. 4, in the present embodiment, the support member 200 has a rectangular shape in a plan view, but is not limited thereto.

A thickness of the insulating base body 201 in the third direction Z is, for example, in a range of 100 μm to 500 μm. Examples of the material of the insulating base body 201 that can be used include resin and ceramic. When ceramic is used as the material of the insulating base body 201, the heat dissipation of the light-emitting device 1 can be increased as compared with a case in which a resin is used. As the ceramic of the insulating base body 201, for example, aluminum nitride or silicon nitride can be used. The insulating base body 201 has a first wiring surface 201A and a second wiring surface 201B opposite to the first wiring surface 201A in the third direction Z.

As illustrated in FIG. 4, the wiring portion includes a first outer wiring portion 212, a second outer wiring portion 213, a first inner wiring portion 232, a second inner wiring portion 233, a third inner wiring portion 242, and a fourth inner wiring portion 243 disposed on the first wiring surface 201A.

As illustrated in FIG. 2, each of the wiring portions on the first wiring surface 201A is bonded and electrically connected to a respective one of the electrodes of the light-emitting elements 100 via bonding members 90. As the bonding member 90, for example, a gold bump or a gold-tin alloy can be used.

The first outer wiring portion 212 extends in the first direction X and the second direction Y on the first wiring surface 201A to have an L shape having a corner portion. The first outer electrode 12 of the outer light-emitting portion 10 is bonded and electrically connected to the first outer wiring portion 212.

The second outer wiring portion 213 is spaced apart from the first outer wiring portion 212 on the first wiring surface 201A. The second outer wiring portion 213 extends in the first direction X and the second direction Y and has an L shape having a corner portion. The second outer electrode 13 of the outer light-emitting portion 10 is bonded and electrically connected to the second outer wiring portion 213.

The first inner wiring portion 232 and the second inner wiring portion 233 are located inward of the first outer wiring portion 212 and the second outer wiring portion 213 on the first wiring surface 201A. The first inner wiring portion 232 extends in the first direction X and the second direction Y on the first wiring surface 201A to have an L shape having a corner portion. The first inner electrode 32 of the frame-shaped inner light-emitting portion 30 is bonded and electrically connected to the first inner wiring portion 232.

The second inner wiring portion 233 is spaced apart from the first inner wiring portion 232 on the first wiring surface 201A. The second inner wiring portion 233 extends in the first direction X and the second direction Y to have an L shape having a corner portion. The second inner electrode 33 of the frame-shaped inner light-emitting portion 30 is bonded and electrically connected to the second inner wiring portion 233.

As long as each of the first outer wiring portion 212, the second outer wiring portion 213, the first inner wiring portion 232, and the second inner wiring portion 233 is bonded to and electrically connected to a respective one of the electrodes of the light-emitting element 100, they need not have a shape having a corner portion in a plan view.

The third inner wiring portion 242 and the fourth inner wiring portion 243 are located inward of the first inner wiring portion 232 and the second inner wiring portion 233 on the first wiring surface 201A. The third inner wiring portion 242 and the fourth inner wiring portion 243 are located on the first wiring surface 201A so as to be spaced apart from each other in the second direction Y, for example. The third inner electrode 42 of the central light-emitting portion 40 is bonded and electrically connected to the third inner wiring portion 242. The fourth inner electrode 43 of the central light-emitting portion 40 is bonded and electrically connected to the fourth inner wiring portion 243. As long as the third inner wiring portion 242 and the fourth inner wiring portion 243 can be respectively bonded to and electrically connected to the third inner electrode 42 and the fourth inner electrode 43, they may be spaced apart from each other in the first direction X on the first wiring surface 201A.

The wiring portions in FIG. 4 correspond to electrodes of the light-emitting element 100 on a one-to-one basis, and the shape of each of the wiring portions in FIG. 4 are similar to the shape of a respective one of electrodes of the light-emitting element 100. Thus, the light-emitting element 100 can be easily positioned by the self-alignment effect until the bonding member 90 is melted and solidified.

As illustrated in FIG. 2, the wiring portion further includes a wiring portion disposed on the second wiring surface 201B. The wiring portion disposed on the first wiring surface 201A and the wiring portion disposed on the second wiring surface 201B are electrically connected to each other via a conductive via or the like penetrating the insulating base body 201. As the material of the wiring portions and the conductive via, for example, copper can be used.

The wiring portions disposed on the second wiring surface 201B include a third outer wiring portion 214, a fourth outer wiring portion 215, a fifth inner wiring portion 234, a sixth inner wiring portion 235, a seventh inner wiring portion 244, and an eighth inner wiring portion 245. The third outer wiring portion 214 is electrically connected to the first outer wiring portion 212. The fourth outer wiring portion 215 is electrically connected to the second outer wiring portion 213. The fifth inner wiring portion 234 is electrically connected to the first inner wiring portion 232. The sixth inner wiring portion 235 is electrically connected to the second inner wiring portion 233. The seventh inner wiring portion 244 is electrically connected to the third inner wiring portion 242. The eighth inner wiring portion 245 is electrically connected to the fourth inner wiring portion 243.

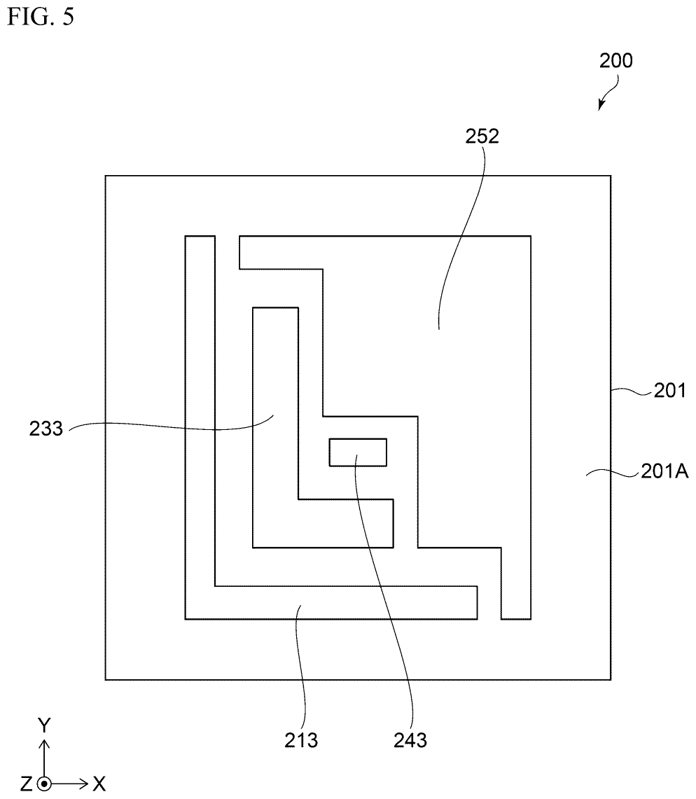

As illustrated in FIGS. 3 and 6, the first inner electrode 32 and the first outer electrode 12 are adjacent to each other in the first direction X and the second direction Y and have the same polarity (in the present embodiment, a polarity to which a cathode potential is applied). In such an arrangement of the first inner electrode 32 and the first outer electrode 12, a common wiring portion provided on the first wiring surface 201A of the support member 200 and connected to the first inner electrode 32 and the first outer electrode 12 can be used. As illustrated in FIG. 5, the support member 200 can include a common wiring portion 252 bonded in common to the first inner electrode 32 and the first outer electrode 12 of a single light-emitting element 100 on the first wiring surface 201A. The first inner electrode 32 and the first outer electrode 12 are bonded to the common wiring portion 252, and the same potential (cathode potential) is applied to the first inner electrode 32 and the first outer electrode 12 through the common wiring portion 252. As compared with a configuration in which the wiring portions (configuration of FIG. 4), each connected to a respective one of the first inner electrode 32 and the first outer electrode 12, are spaced apart from each other, the area of the wiring portion can be increased by using the common wiring portion 252, and thus the heat dissipation can be further improved.

The light-emitting device 1 can be configured such that lighting of the outer light-emitting portion 10, the frame-shaped light-emitting portion (frame-shaped inner light-emitting portion 30), and the central light-emitting portion 40 can be controlled independently from each other. For example, by adjusting electric power to be supplied to each of the outer light-emitting portion 10, the frame-shaped light-emitting portion (frame-shaped inner light-emitting portion 30), and the central light-emitting portion 40 in accordance with a region to be irradiated with light, turning on or off of the light-emitting portions or the intensity of light emission can be controlled.

### Wavelength Conversion Member

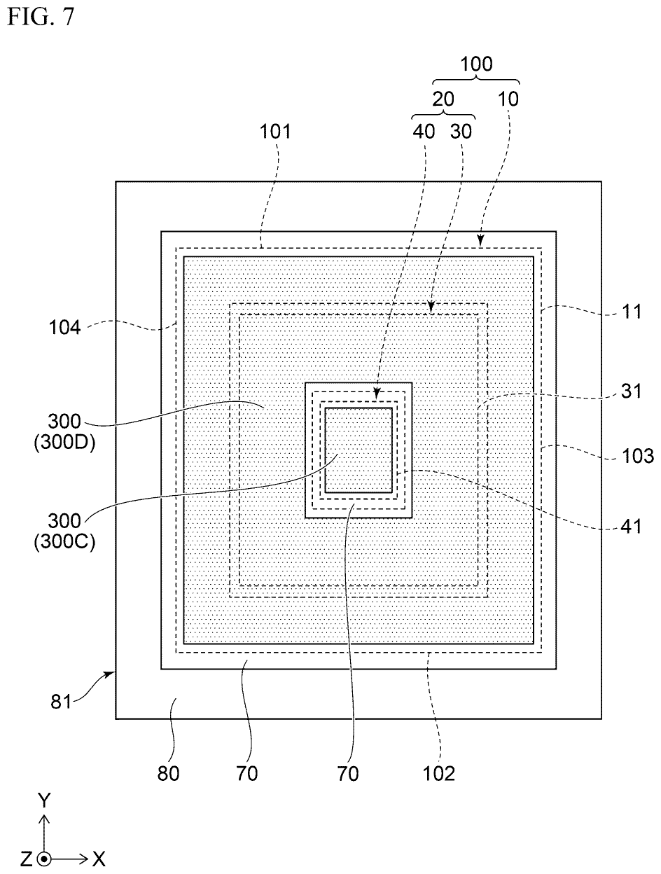

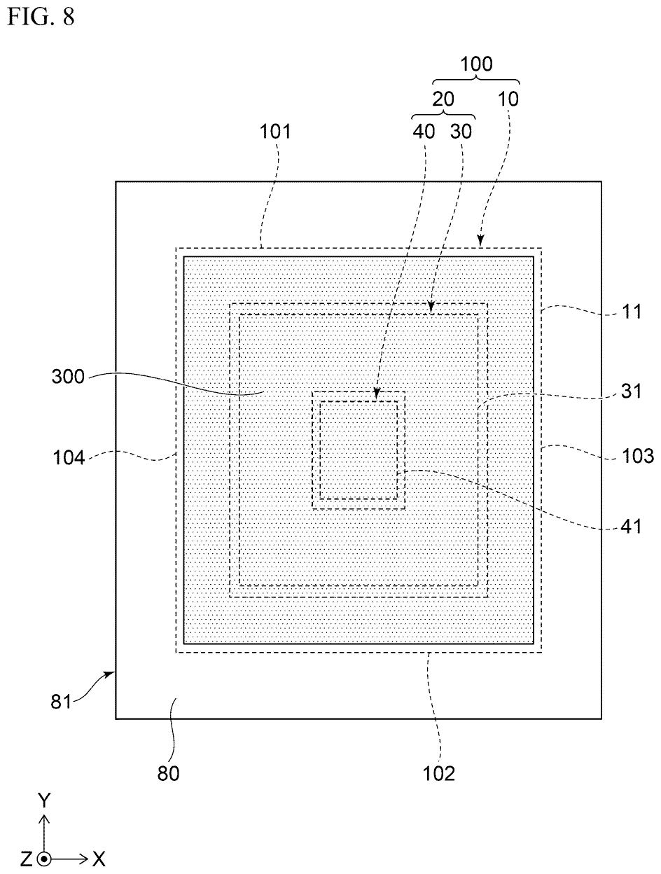

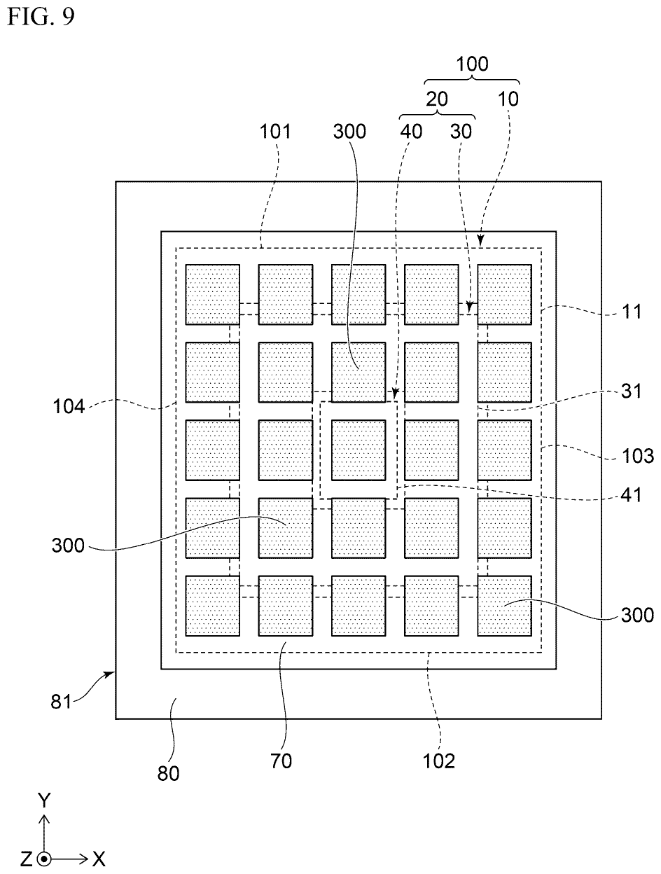

As illustrated in FIG. 2, the light-emitting device 1 can further include a wavelength conversion member 300 disposed on the outer light-emitting surface 11A of the outer light-emitting portion 10 and on the inner light-emitting surfaces (the frame-shaped inner light-emitting surface 31A and the central inner light-emitting surface 41A) of the inner light-emitting portion 20. In FIG. 1, FIG. 7, FIG. 8, or FIG. 9, for convenience of explanation, the wavelength conversion member 300 is indicated by dot hatching in order to facilitate distinguishing the semiconductor structures from the wavelength conversion member 300.

The wavelength conversion member 300 converts the wavelength of at least a part of light emitted by the outer light-emitting portion 10 and the inner light-emitting portion 20 (specifically, light emitted by the outer semiconductor structure 11 and the inner semiconductor structure). The light-emitting device 1 emits light in which light emitted by the outer light-emitting portion 10 and the inner light-emitting portion 20 and light wavelength-converted by the wavelength conversion member 300 are mixed.

In the present embodiment, the wavelength conversion member 300 includes a phosphor layer 301 disposed on the outer light-emitting surface 11A of the outer light-emitting portion 10 and the inner light-emitting surfaces (the frame-shaped inner light-emitting surface 31A and the central inner light-emitting surface 41A) of the inner light-emitting portion 20, a light diffusion layer 302 disposed on the phosphor layer 301, and a light-transmissive layer 303 disposed on the light diffusion layer 302. The wavelength conversion member 300 may include at least the phosphor layer 301.

The phosphor layer 301 includes, for example, a resin base material and a wavelength conversion substance. As the material of the resin base material of the phosphor layer 301, for example, a thermosetting resin, such as a silicone resin, a modified silicone resin, an epoxy resin, a modified epoxy resin, or a phenol resin, can be used. Among these, particularly, a silicone resin or a modified silicone resin with good light resistance and heat resistance is preferably used.

Examples of the wavelength conversion substance of the phosphor layer 301 that can be used include an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), oxynitride-based phosphors such as a β-SiAlON-based phosphor (for example, (Si,Al)₃(O,N)₄:Eu) and an α-SiAlON-based phosphor (for example, Ca(Si,Al)₁₂(O,N)₁₆:Eu), nitride-based phosphors such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), and an SCASN-based phosphor (for example, (Sr,Ca)AlSiN₃:Eu), fluoride-based phosphors such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), and an MGF-based phosphor (for example, 3.5MgO/·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a II-VI group quantum dot (for example, CdSe), a III-V group quantum dot (for example, InP), and a quantum dot having a chalcopyrite structure (for example, (Ag,Cu)(In,Ga)(S,Se)₂).

The phosphor layer 301 may include one type of wavelength conversion substance, or may include a plurality of types of wavelength conversion substances.

The light diffusion layer 302 diffuses light emitted by the outer light-emitting portion 10 and the inner light-emitting portion 20 and light wavelength-converted by the phosphor layer 301. The light diffusion layer 302 can include, for example, the resin base material exemplified for the phosphor layer 301 and a light diffusion substance. As the light diffusion substance included in the light diffusion layer 302, for example, titanium oxide or silicon oxide can be used.

The light-transmissive layer 303 can include, for example, the resin base material exemplified for the phosphor layer 301. The light-transmissive layer 303 includes no light diffusion substance. The transmittance of the light-transmissive layer 303 is higher than the transmittance of the light diffusion layer 302 with respect to the light emitted by the outer light-emitting portion 10 and the inner light-emitting portion 20 and the light wavelength-converted by the phosphor layer 301.

The wavelength conversion member 300 is adhered to the outer light-emitting surface 11A of the outer light-emitting portion 10 and the inner light-emitting surface of the inner light-emitting portion 20 by an adhesive layer. The adhesive layer is light-transmissive to the light emitted by the outer light-emitting portion 10 and the inner light-emitting portion 20 such that the light emitted by the outer light-emitting portion 10 and the inner light-emitting portion 20 is incident on the wavelength conversion member 300. Examples of the material of the adhesive layer that can be used include thermoplastic resins such as an acrylic resin, a polycarbonate resin, a cyclic polyolefin resin, a polyethylene terephthalate resin, and a polyester resin, and thermosetting resins such as an epoxy resin and a silicone resin.

Alternatively, the wavelength conversion member 300 may be directly bonded to the outer light-emitting surface 11A of the outer light-emitting portion 10 and the inner light-emitting surface of the inner light-emitting portion 20. In other words, there may be a case in which no adhesive layer is disposed between the wavelength conversion member 300 and each of the light-emitting surfaces of the outer light-emitting portion 10 and the inner light-emitting portion 20. Thus, light emitted from any one of the outer light-emitting portion 10, the frame-shaped inner light-emitting portion 30, and the central light-emitting portion 40 can be inhibited from propagating through the inside of the adhesive layer to spread in the lateral direction (direction along the XY plane) and thus traveling toward the other light-emitting portions. This makes it possible to obtain a light-emitting device with a high contrast (a luminance ratio between a turned-on light-emitting portion and a turned-off light-emitting portion).

In the example illustrated in FIG. 1, the wavelength conversion member 300 can include an outer wavelength conversion member 300A disposed on the outer light-emitting portion 10, an inner wavelength conversion member 300B disposed on the frame-shaped inner light-emitting portion 30, and a central wavelength conversion member 300C disposed on the central light-emitting portion 40.

In a plan view, the outer wavelength conversion member 300A has a frame shape similar to that of the outer light-emitting portion 10. In a plan view, the inner wavelength conversion member 300B is located inward of the outer wavelength conversion member 300A, and has a frame shape similar to that of the frame-shaped inner light-emitting portion 30. In a plan view, the central wavelength conversion member 300C is located inward of the inner wavelength conversion member 300B, and has a rectangular shape similar to that of the outer edge of the central light-emitting portion 40.

The width of the outer wavelength conversion member 300A in the first direction X is smaller than the width of the outer light-emitting surface 11A of the outer light-emitting portion 10 in the first direction X, and the width of the outer wavelength conversion member 300A in the second direction Y is smaller than the width of the outer light-emitting surface 11A in the second direction Y.

The width of the inner wavelength conversion member 300B in the first direction X is smaller than the width of the frame-shaped inner light-emitting surface 31A of the frame-shaped inner light-emitting portion 30 in the first direction X, and the width of the inner wavelength conversion member 300B in the second direction Y is smaller than the width of the frame-shaped inner light-emitting surface 31A in the second direction Y.

The width of the central wavelength conversion member 300C in the first direction X is smaller than the width of the central inner light-emitting surface 41A of the central light-emitting portion 40 in the first direction X, and the width of the central wavelength conversion member 300C in the second direction Y is smaller than the width of the central inner light-emitting surface 41A in the second direction Y.

A separation distance between the outer wavelength conversion member 300A and the inner wavelength conversion member 300B in the first direction X and a separation distance between the inner wavelength conversion member 300B and the central wavelength conversion member 300C in the first direction X are, for example, in a range of 10 μm to 200 μm. A separation distance between the outer wavelength conversion member 300A and the inner wavelength conversion member 300B in the second direction Y and a separation distance between the inner wavelength conversion member 300B and the central wavelength conversion member 300C in the second direction Y are, for example, in a range of 10 μm to 200 μm.

The outer wavelength conversion member 300A and the inner wavelength conversion member 300B may be continuous with each other in the first direction X and the second direction Y to form one frame-shaped wavelength conversion member 300D disposed on the outer light-emitting portion 10 and the frame-shaped inner light-emitting portion 30 as illustrated in FIG. 7. In this case, two light-emitting portions (the outer light-emitting portion 10 and the frame-shaped inner light-emitting portion 30) are disposed below one wavelength conversion member 300, so that spacing between the two light-emitting portions can be less noticeable when the two light-emitting portions are turned on or off. In addition, the number of wavelength conversion members 300 disposed on one light-emitting element 100 is smaller than that in the example illustrated in FIG. 1, so that manufacturing of the light-emitting device 1 is facilitated.

In addition, as illustrated in FIG. 8, one wavelength conversion member 300 continuous in the first direction X and the second direction Y may be disposed on the outer light-emitting portion 10, on the frame-shaped inner light-emitting portion 30, and on the central light-emitting portion 40. In this case, three light-emitting portions (the outer light-emitting portion 10, the frame-shaped inner light-emitting portion 30, and the central light-emitting portion 40) are disposed below one wavelength conversion member 300, which allows spacing between the three light-emitting portions to be less noticeable when the three light-emitting portions are turned on or off. In addition, in this case, a single wavelength conversion member 300 is disposed on a single light-emitting element 100, which allows for further facilitating the manufacturing.

Alternatively, as illustrated in FIG. 9, a plurality of wavelength conversion members 300 each having a rectangular shape in a plan view may be arranged in the first direction X and the second direction Y. In the example illustrated in FIG. 9, 25 wavelength conversion members 300 are arranged in a 5×5 matrix.

### First Resin Member

As illustrated in FIG. 2, the light-emitting device 1 can further include a first resin member 60. The first resin member 60 is disposed on the first wiring surface 201A of the insulating base body 201, and is located between the outer light-emitting portion 10 and the frame-shaped inner light-emitting portion 30 and between the frame-shaped inner light-emitting portion 30 and the central light-emitting portion 40. The first resin member 60 is located between the outer electrode surface 11B of the outer semiconductor structure 11 and the first wiring surface 201A, between the frame-shaped inner electrode surface 31B of the frame-shaped inner semiconductor structure 31 and the first wiring surface 201A, and between the central inner electrode surface 41B of the central inner semiconductor structure 41 and the first wiring surface 201A. The first resin member 60 covers lateral surfaces of the light-emitting portions, lateral surfaces of the wiring portions on the first wiring surface 201A, and lateral surfaces of the bonding member 90. The first resin member 60 is not disposed on the light-emitting surface of each light-emitting portion, and the light-emitting surface of each light-emitting portion and an upper surface of the first resin member 60 are on the same XY plane.

The first resin member 60 has insulating properties. The first resin member 60 has light reflectivity with respect to the light emitted by the outer light-emitting portion 10 and the inner light-emitting portion 20. The first resin member 60 can include, for example, the resin base material exemplified for the phosphor layer 301 and a light diffusive substance. As a resin base material of the first resin member 60, a silicone resin or a silicone-modified resin having good resistance to light and heat. Examples of the light diffusive substance that can be used include titanium oxide and silicon oxide.

With the light-reflective first resin member 60 disposed between the light-emitting portions, when one of the outer light-emitting portion 10, the frame-shaped inner light-emitting portion 30, and the central light-emitting portion 40 is caused to emit light and the other light-emitting portions is not caused to emit light, light emitted from the one light-emitting portion is less likely to travel to sides of the light-emitting portions not caused to emit light. This makes it possible to obtain the light-emitting device 1 with a high contrast.

The first resin member 60 is located outside the outer light-emitting portion 10 in a plan view, and covers the outermost lateral surface, on the outer edge side, of the outer light-emitting portion 10. With this structure, emission of light to the outside of the outer light-emitting portion 10 can be reduced, which can reduce loss of light, and the light-emitting device 1 with a high contrast can be obtained.

### Second Resin Member

The light-emitting device 1 can further include a second resin member 70. The wavelength conversion member 300 is held by the second resin member 70. In the present embodiment, the plurality of wavelength conversion members 300 are integrally held by the second resin member 70.

The second resin member 70 is disposed on the first resin member 60. In addition, the second resin member 70 is disposed between the wavelength conversion members 300 adjacent to each other in the lateral direction. In the example illustrated in FIG. 1, the second resin member 70 is disposed between the outer wavelength conversion member 300A and the inner wavelength conversion member 300B and between the inner wavelength conversion member 300B and the central wavelength conversion member 300C. The second resin member 70 covers the lateral surfaces of each wavelength conversion member 300. The second resin member 70 is not disposed on the upper surface of each wavelength conversion member 300, and the upper surface of each wavelength conversion member 300 is exposed from the second resin member 70. In the example illustrated in FIG. 2, the upper surface of the second resin member 70 and the upper surfaces of the wavelength conversion members 300 are on the same XY plane, and the light-emitting surface of the light-emitting device 1 includes the upper surfaces of the wavelength conversion members 300.

The second resin member 70 has light reflectivity with respect to the light emitted by the outer light-emitting portion 10 and the inner light-emitting portion 20 and the light wavelength-converted by the wavelength conversion member 300. The second resin member 70, for example, can have a configuration similar to the first resin member 60.

With the light-reflective second resin member 70 located between the adjacent wavelength conversion members 300, light propagation in the lateral direction between the outer wavelength conversion member 300A, the inner wavelength conversion member 300B, and the central wavelength conversion member 300C (hereinafter referred to as wavelength conversion members 300A, 300B, and 300C in some cases) can be reduced as will be described below, so that a light-emitting device with a high contrast can be obtained. For example, when one of the outer light-emitting portion 10, the frame-shaped inner light-emitting portion 30, and the central light-emitting portion 40 emits light and the other light-emitting portions emit no light, the likelihood of the incidence of light emitted by the one light-emitting portion onto the wavelength conversion member 300 on the light-emitting portions emitting no light and the emission of the wavelength conversion substance included in the wavelength conversion member 300 on the light-emitting portions emitting no light can be reduced. This makes it possible to obtain the light-emitting device 1 with a high contrast.

The second resin member 70 is located outside the outer wavelength conversion member 300A in a plan view, and covers the outermost surface on the outer edge side of the outer wavelength conversion member 300A. With this structure, emission of light to the outside of the outer wavelength conversion member 300A can be reduced, which allows for reducing loss of light, and the light-emitting device 1 having a high contrast can be obtained.

In the present embodiment, with the light-emitting device 1 including the light diffusion layer 302, when the light-emitting device 1 is viewed from the light-emitting surface side during non-emission, the color of the appearance of the wavelength conversion member 300 and the color of the appearance of the second resin member 70 can be close to each other, and the light-emitting device can have a good appearance in which the color difference between the wavelength conversion member 300 and the second resin member 70 during the non-emission is reduced. The concentration of the light diffusion substance in the light diffusion layer 302 is preferably lower than the concentration of the light diffusive substance in the second resin member 70. Thus, light can be easily extracted from the wavelength conversion member 300.

### Third Resin Member

The light-emitting device 1 can further include a third resin member 80. The third resin member 80 is disposed in an outer peripheral region on the first wiring surface 201A of the insulating base body 201. The light-emitting portion and the wavelength conversion member 300 are not located in the outer peripheral region. The third resin member 80 covers the upper surface and the lateral surfaces of the first resin member 60 and the lateral surfaces of the second resin member 70 in the outer peripheral region.

The third resin member 80 has light reflectivity with respect to the light emitted by the outer light-emitting portion 10 and the inner light-emitting portion 20 and the light wavelength-converted by the wavelength conversion member 300. The third resin member 80, for example, can have a configuration similar to the first resin member 60. Note that at least one of the first resin member 60, the second resin member 70, or the third resin member 80 may be different from the other in the type, content, and the like of the constituent components.

With the third resin member 80, the emission of light to the outside of the light-emitting device 1 can be further reduced, which can reduce the loss of light, and the light-emitting device 1 having a high contrast can be obtained.

Thus, the light-emitting device 1 incudes a resin member 81 including the first resin member 60, the second resin member 70, and the third resin member 80. In the present embodiment, the first resin member 60, the second resin member 70, and the third resin member 80 have configurations similar to each other. Even if the type, content, or the like of the constituent component of at least one of them are different from the other of them, the first resin member 60, the second resin member 70, and the third resin member 80 can be collectively regarded as the resin member 81. In one example, the first resin member 60, the second resin member 70, and the third resin member 80 are not clearly distinguished from each other in the resin member 81.

### Light-Emitting Device According to Second Embodiment

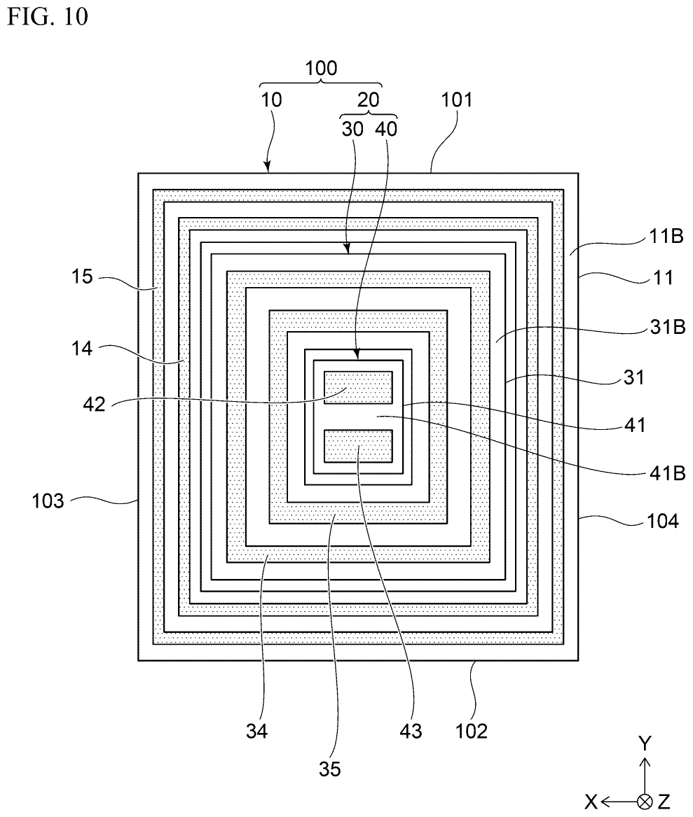

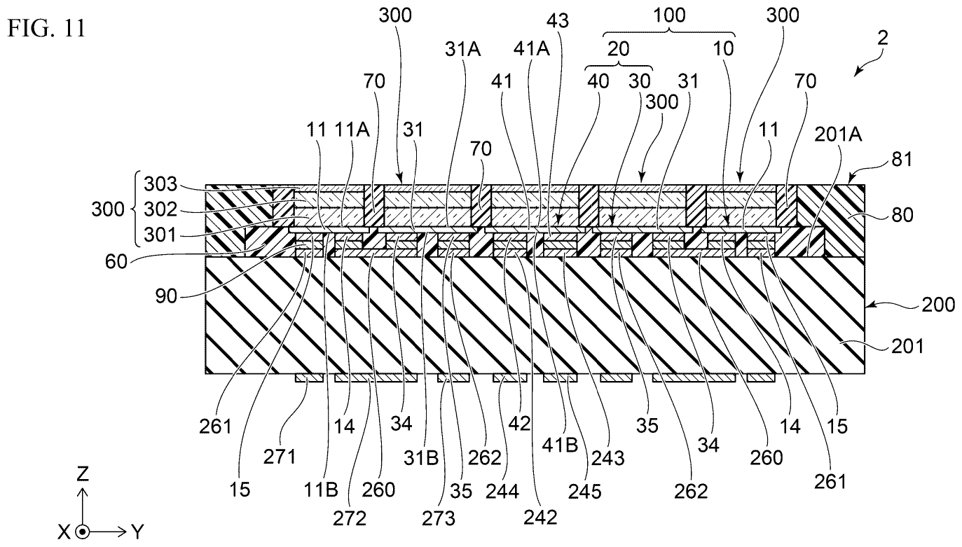

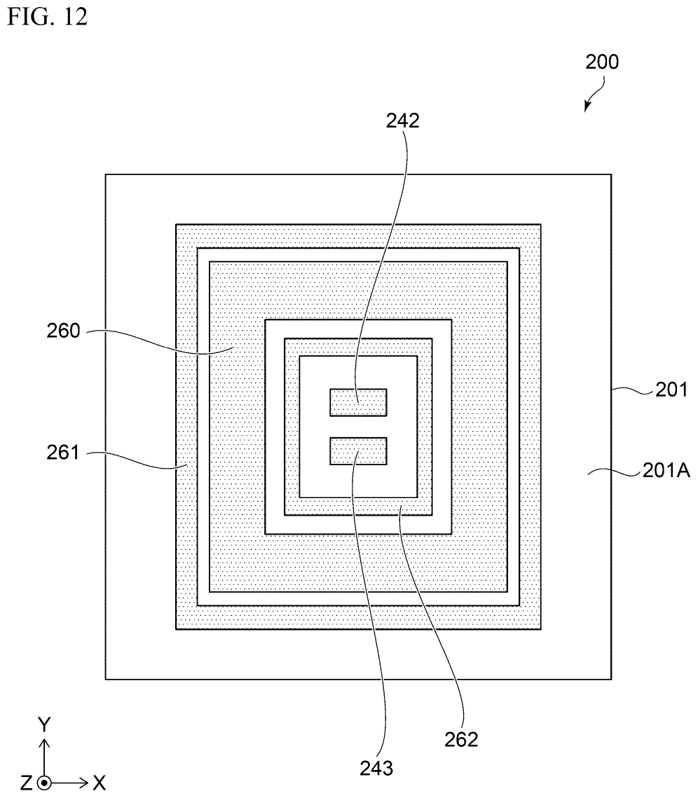

A light-emitting device 2 according to a second embodiment is described below with reference to FIGS. 10 to 12. The plan view of a light-emitting surface side of the light-emitting device 2 according to the second embodiment is illustrated in FIG. 1, FIG. 7, FIG. 8, or FIG. 9 as in the first embodiment. For example, a cross section illustrated in FIG. 11 corresponds to the cross section taken along line II-II in FIG. 1. In FIG. 10, in order to easily distinguish electrodes from semiconductor structures, the electrodes are indicated by dot hatching. In FIG. 12, in order to facilitate the description of a region of a wiring portion, the wiring portion is indicated by dot hatching. The light-emitting device 2 according to the second embodiment is different from the light-emitting device 1 according to the first embodiment mainly in the configurations of outer electrodes and inner electrodes.

The light-emitting device 2 includes the support member 200 and the light-emitting element 100 disposed on the support member 200. The light-emitting element 100 includes the inner light-emitting portion 20 and the outer light-emitting portion 10. An outermost surface of the light-emitting element 100 being the light-emitting surface thereof include the inner light-emitting surface of the inner semiconductor structure (the frame-shaped inner semiconductor structure 31 and the central inner semiconductor structure 41) and the outer light-emitting surface of the outer semiconductor structure 11.

In the light-emitting device 2 according to the second embodiment, configurations different from the configurations of the light-emitting device 1 according to the first embodiment are mainly described below.

As illustrated in FIG. 10, outer electrodes include a first outer electrode 14 and a second outer electrode 15 disposed on the outer electrode surface 11B of the outer semiconductor structure 11. The first outer electrode 14 is a cathode electrode in the outer light-emitting portion 10, and the second outer electrode 15 is an anode electrode in the outer light-emitting portion 10.

In a plan view, the first outer electrode 14 has a rectangular frame shape that is continuous along the first outer edge 101, the second outer edge 102, the third outer edge 103, and the fourth outer edge 104. In a plan view, the second outer electrode 15 has a rectangular frame shape that is continuous along the first outer edge 101, the second outer edge 102, the third outer edge 103, and the fourth outer edge 104. The first outer electrode 14 is located inward of the second outer electrode 15 on the outer electrode surface 11B of the outer semiconductor structure 11. The shape of the first outer electrode 14 and the second outer electrode 15 in a plan view may be a shape in which corner portions of the rectangle are chamfered, and is not limited to a rectangle as long as each of them is continuous in a frame shape.

Inner electrodes include a first inner electrode 34 and a second inner electrode 35 disposed on the frame-shaped inner electrode surface 31B of the frame-shaped inner semiconductor structure 31. The first inner electrode 34 is a cathode electrode in the frame-shaped inner light-emitting portion 30, and the second inner electrode 35 is an anode electrode in the frame-shaped inner light-emitting portion 30.

In a plan view, the first inner electrode 34 has a rectangular frame shape that is continuous along the first outer edge 101, the second outer edge 102, the third outer edge 103, and the fourth outer edge 104. In a plan view, the second inner electrode 35 has a rectangular frame shape that is continuous along the first outer edge 101, the second outer edge 102, the third outer edge 103, and the fourth outer edge 104. The second inner electrode 35 is located inward of the first inner electrode 34 on the frame-shaped inner electrode surface 31B of the frame-shaped inner semiconductor structure 31. The shape of the first inner electrode 34 and the second inner electrode 35 in a plan view may be a shape in which corner portions of the rectangle are chamfered, and is not limited to a rectangle as long as each of them is continuous in a frame shape.

The inner electrodes include a third inner electrode 42 and a fourth inner electrode 43 disposed on the central inner electrode surface 41B of the central inner semiconductor structure 41. In a plan view, the third inner electrode 42 and the fourth inner electrode 43 are located inward of the second inner electrode 35. The third inner electrode 42 is a cathode electrode in the central light-emitting portion 40, and the fourth inner electrode 43 is an anode electrode in the central light-emitting portion 40. The third inner electrode 42 and the fourth inner electrode 43 are spaced apart from each other in the second direction Y, for example. The third inner electrode 42 and the fourth inner electrode 43 may be spaced apart from each other in the first direction X.

With the outer electrodes 14 and 15 and the inner electrodes 34 and 35 each formed in a frame shape that is continuous along the first outer edge 101, the second outer edge 102, the third outer edge 103, and the fourth outer edge 104, the area of each electrode can be increased. Thus, the heat dissipation of the light-emitting device 2 can be improved.

In a plan view, the first outer electrode 14 and the first inner electrode 34 are disposed between the second outer electrode 15 and the second inner electrode 35. The first outer electrode 14 being a cathode electrode in the outer light-emitting portion 10 and the first inner electrode 34 being a cathode electrode in the frame-shaped inner light-emitting portion 30 are adjacent to each other in the first direction X and the second direction Y.

As illustrated in FIG. 12, the support member 200 includes one common wiring portion 260. The common wiring portion 260 is disposed on the first wiring surface 201A of the insulating base body 201. In a plan view, the common wiring portion 260 has a rectangular frame shape. The first outer electrode 14 and the first inner electrode 34 of a single light-emitting element 100 are bonded to the common wiring portion 260.

The first outer electrode 14 and the first inner electrode 34 of the light-emitting element 100, which are adjacent to each other in a plan view and to which the same polarity (cathode potential) is given, are bonded to and electrically connected to the common wiring portion 260. As compared with a configuration in which respective wiring portions connected to the first outer electrode 14 and the first inner electrode 34 are spaced apart from each other, in the present embodiment, the area of the wiring portion can be increased by using the common wiring portion 260, and the heat dissipation can be improved.

The support member 200 further includes an outer wiring portion 261 and an inner wiring portion 262 disposed on the first wiring surface 201A of the insulating base body 201. Each of the outer wiring portion 261 and the inner wiring portion 262 has a rectangular frame shape in a plan view. In a plan view, the common wiring portion 260 is located between the outer wiring portion 261 and the inner wiring portion 262.

The second outer electrode 15 of the outer light-emitting portion 10 is bonded and electrically connected to the outer wiring portion 261. The second inner electrode 35 of the frame-shaped inner light-emitting portion 30 is bonded and electrically connected to the inner wiring portion 262.

Note that the shape of each of the common wiring portion 260, the outer wiring portion 261, and the inner wiring portion 262 in a plan view may be a shape in which corner portions of the rectangle are chamfered, and is not limited to a rectangle as long as each of them is continuous in a frame shape.

The support member 200 further includes a third inner wiring portion 242 and a fourth inner wiring portion 243 disposed on the first wiring surface 201A of the insulating base body 201. The third inner wiring portion 242 and the fourth inner wiring portion 243 are located inward of the inner wiring portion 262 on the first wiring surface 201A. The third inner wiring portion 242 and the fourth inner wiring portion 243 are located on the first wiring surface 201A so as to be spaced apart from each other in the second direction Y, for example. Alternatively, the third inner wiring portion 242 and the fourth inner wiring portion 243 may be spaced apart from each other in the first direction X on the first wiring surface 201A.

The third inner electrode 42 of the central light-emitting portion 40 is bonded and electrically connected to the third inner wiring portion 242. The fourth inner electrode 43 of the central light-emitting portion 40 is bonded and electrically connected to the fourth inner wiring portion 243.

### Light-Emitting Module

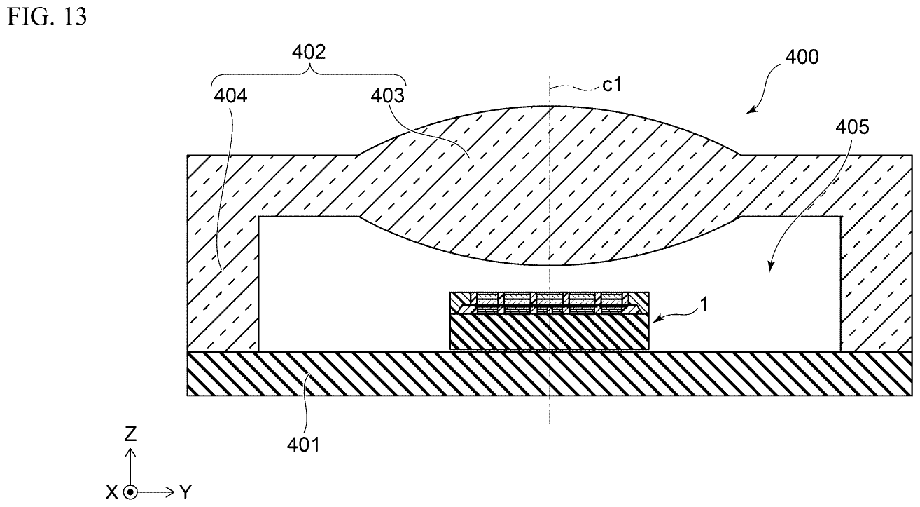

A light-emitting module according to one embodiment will be described below with reference to FIG. 13.

A light-emitting module 400 illustrated in FIG. 13 includes the light-emitting device 1 according to the first embodiment described above, and a lens 402 disposed on the inner light-emitting surface and the outer light-emitting surface of the light-emitting device 1. The light-emitting module 400 may include the light-emitting device 2 according to the second embodiment instead of the light-emitting device 1.

The light-emitting module 400 includes a mounting substrate 401. The mounting substrate 401 has an upper surface, and the light-emitting device 1 is disposed on the upper surface of the mounting substrate 401. The mounting substrate 401 includes a circuit unit to which electric power is supplied from a power supply. The wiring portion disposed on the second wiring surface 201B of the support member 200 of the light-emitting device 1 is electrically connected to the circuit unit of the mounting substrate 401. In the schematic diagrams showing the light-emitting module, illustration of the circuit unit included in the mounting substrate 401 is omitted to avoid excessive complication of the drawings.

The lens 402 includes a lens portion 403 and a lens support portion 404 that supports the lens portion 403. The lens portion 403 and the lens support portion 404 are monolithically formed with each other. The lens support portion 404 is disposed on the mounting substrate 401 via an adhesive member. An air layer 405 is present between the light-emitting device 1 and the lens 402. The lens 402 is made of, for example, a resin such as a polycarbonate resin, an acrylic resin, an epoxy resin, or a silicone resin, or glass. The lens portion 403 is a double-sided convex lens. A central axis c1 of the lens portion 403 extends in the first direction Z. In a plan view, the central axis c1 of the lens portion 403 overlaps the center of the light-emitting device 1. In the present embodiment, the center of the light-emitting device 1 is the center of the central light-emitting portion 40.

The light-emitting module 400 including the light-emitting device 1 can be used as a flash light source for an imaging device, for example. The imaging device can be mounted on, for example, a mobile communication terminal. As described above with reference to FIG. 1 and the like, in the light-emitting device 1, the inner light-emitting portion 20 includes the rectangular central light-emitting portion 40 located at the center of the inner light-emitting portion 20. In a case in which the light-emitting module 400 is used as a flash light source when the imaging device captures an image, the central light-emitting portion 40 emits light to a central region in a light irradiation region. In general, a range of a scene captured in a captured image is rectangular, and the light-emitting module 400 is configured to allow switching between, for example, a narrow-angle mode in which only the central light-emitting portion 40 emits light and a wide-angle mode in which all light-emitting portions including the central light-emitting portion 40, the frame-shaped light-emitting portion, and the outer light-emitting portion 10 emit light. The narrow-angle mode has a narrower light irradiation angle than the wide-angle mode. When the light-emitting device 1 can control the turning on and turning off of each of the outer light-emitting portion 10, the frame-shaped light-emitting portion (frame-shaped inner light-emitting portion 30), and the central light-emitting portion 40 in accordance with the narrow-angle mode or the wide-angle mode, photography according to a photography mode in the imaging device, such as telephoto mode or close-up mode, is possible, for example. In addition, in the wide-angle mode, an irradiation angle can be adjusted by controlling the light emission intensity of each light-emitting portion.

In the light-emitting module 400 illustrated in FIG. 13, the amount of change in a light distribution angle of the central light-emitting portion 40 caused by the lens 402 is larger than the amount of change in a light distribution angle of the outer light-emitting portion 10 caused by the lens 402. This is because the distance between the central light-emitting portion 40 and the central axis c1 of the lens 402 is smaller than the distance between the outer light-emitting portion 10 and the central axis c1 of the lens 402. In the present specification, the amount of change in the light distribution angle is an absolute value of the difference between a light distribution angle of light emitted from a light-emitting portion (here, the central light-emitting portion 40 or the outer light-emitting portion 10) when no lens is provided above the light-emitting surface of the light-emitting device and a light distribution angle of light emitted from a light-emitting portion (here, the central light-emitting portion 40 or the outer light-emitting portion 10) and transmitted through a lens when the lens is provided above the light-emitting surface of the light-emitting device. The “distance” here refers to a maximum length between the outer edge of the central light-emitting portion 40 and the central axis c1 of the lens 402 and a minimum length between the inner edge of the outer light-emitting portion 10 and the central axis c1 of the lens 402 in an arbitrary direction in a plan view. The amount of change in the light distribution angle of the light-emitting portion caused by the lens is described below with reference to an example. For example, in the present embodiment, when the light distribution angle of light emitted from the central light-emitting portion 40 is 118°, the light distribution angle of light emitted from the central light-emitting portion 40 and transmitted through the lens 402 (specifically, the lens portion 403) is 30°. At this time, the amount of change in the light distribution angle is 88° (=118°−30°). When the light distribution angle of the light emitted from the outer light-emitting portion 10 is 118°, the light distribution angle of the light emitted from the outer light-emitting portion 10 and transmitted through the lens 402 (specifically, the lens portion 403) is 140°. At this time, the amount of change in the light distribution angle is 22° (=118°−140°). Accordingly, in the light-emitting module 400, it can be said that the amount of change in the light distribution angle of the central light-emitting portion 40 caused by the lens 402 (lens portion 403) is larger than the amount of change in the light distribution angle of the outer light-emitting portion 10 caused by the lens 402 (lens portion 403). Because “the sizes of the central light-emitting portion 40, the outer light-emitting portion 10, and the light-emitting module 400” are negligibly small with respect to “the distance between each of the central light-emitting portion 40, the outer light-emitting portion 10, and the light-emitting module 400 and a light receiver for measuring a light distribution angle,” the light distribution angle of light emitted from the central light-emitting portion 40 and the light distribution angle of light emitted from the outer light-emitting portion 10 when the lens 402 is not provided above the light-emitting surface of the light-emitting module 400 can be regarded as equivalent values.

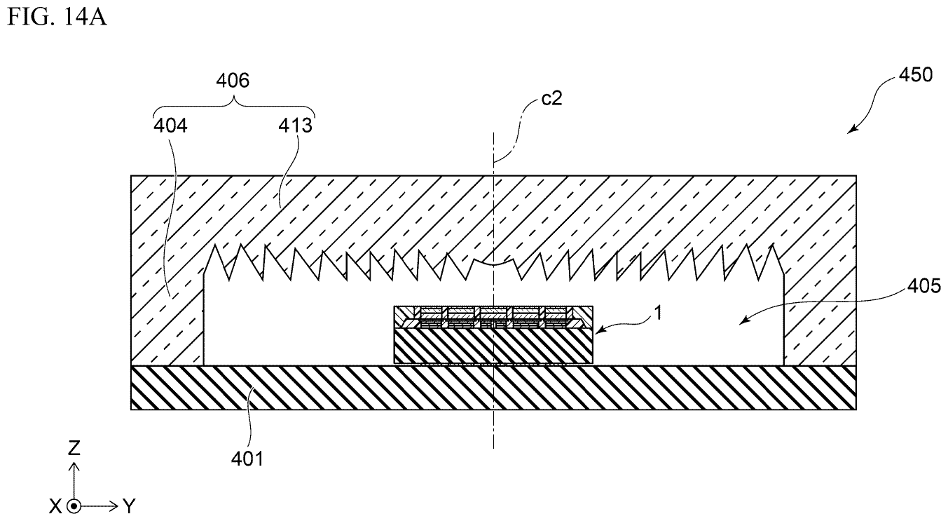

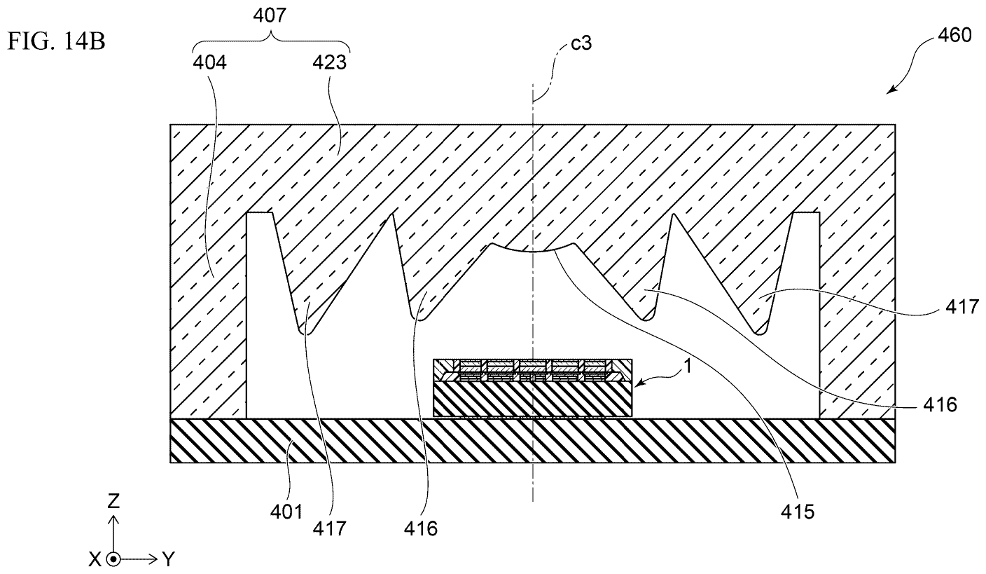

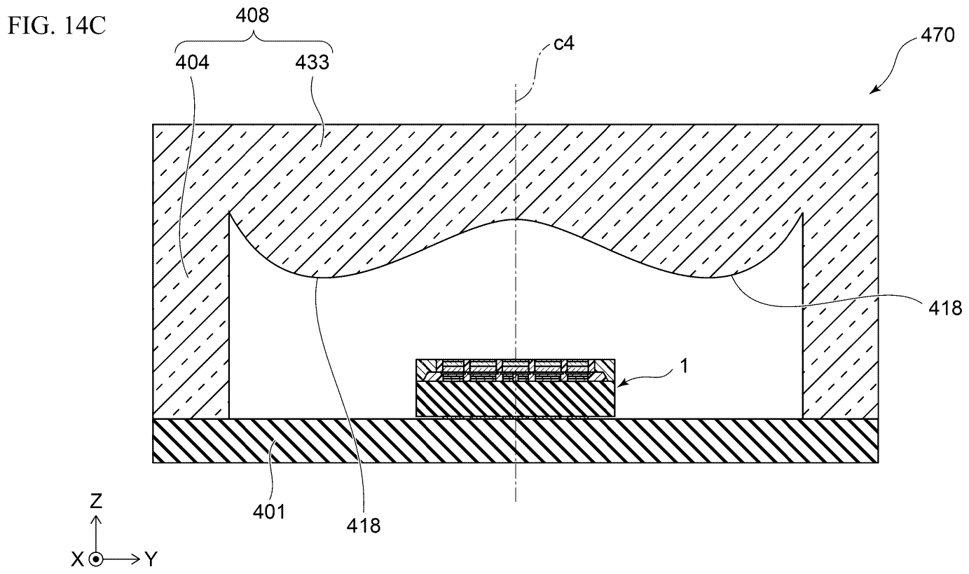

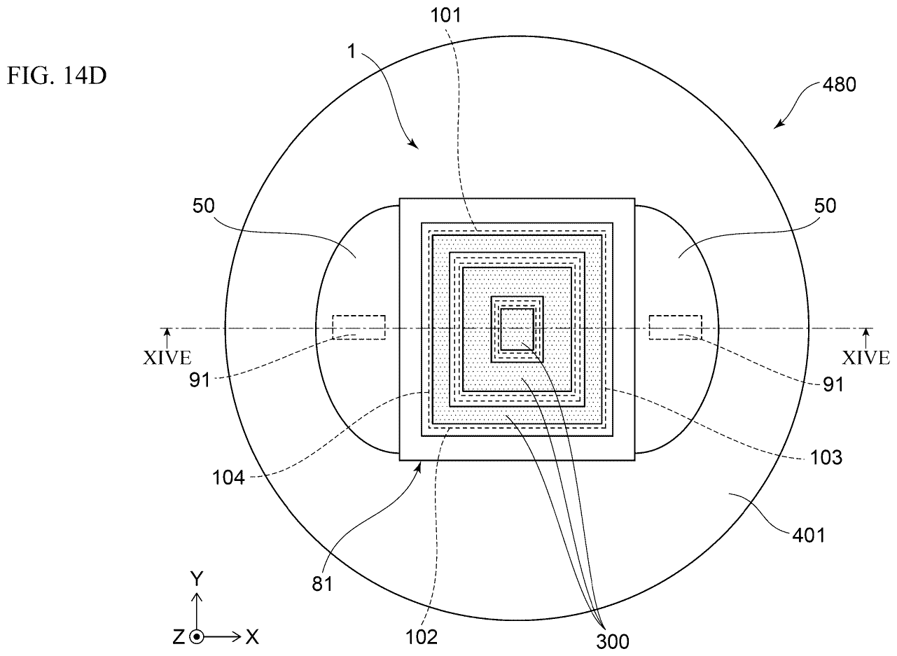

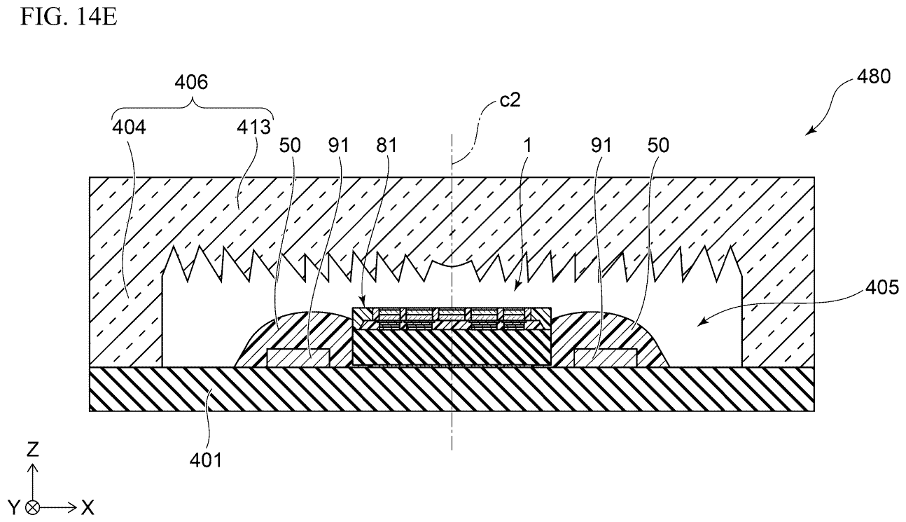

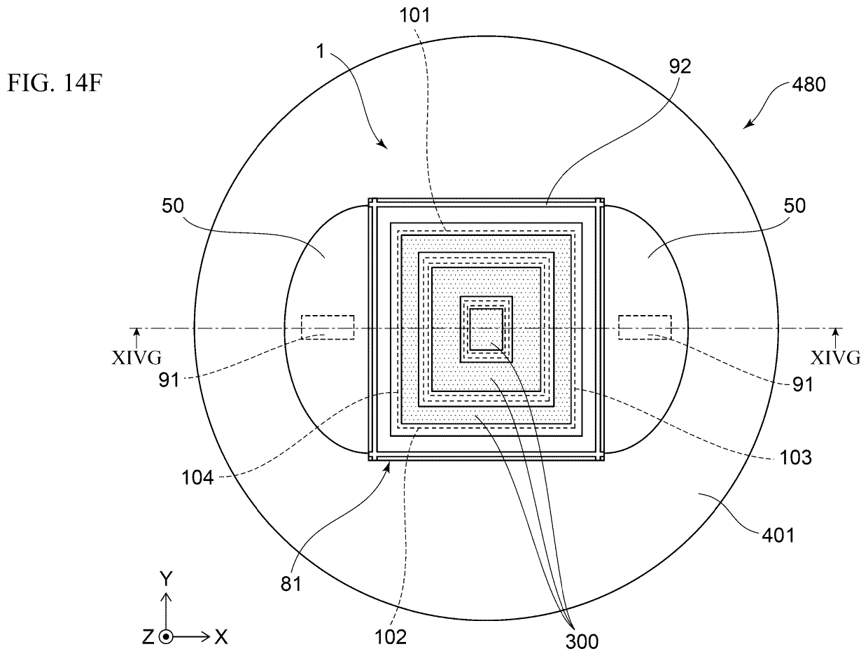

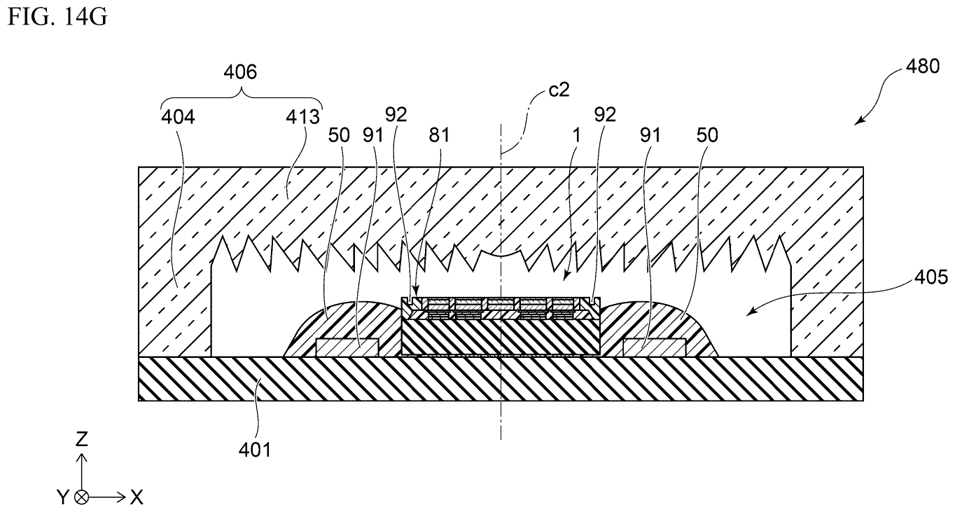

Modified examples of the light-emitting module 400 are illustrated in FIGS. 14A, 14B and 14C. FIG. 14A is a schematic cross-sectional view illustrating a light-emitting module 450 according to a first modified example. FIG. 14B is a schematic cross-sectional view illustrating a light-emitting module 460 according to a second modified example. FIG. 14C is a schematic cross-sectional view illustrating a light-emitting module 470 according to a third modified example.

The light-emitting module 450 according to the first modified example is different from the light-emitting module 400 in that a lens 406 including a lens portion 413 is provided. The lens 406 includes the lens portion 413 and a lens support portion 404 that supports the lens portion 413.

As illustrated in FIG. 14A, in the light-emitting module 450, a Fresnel lens having a flat light emission surface and a light incident surface provided with a plurality of convex portions is used as the lens portion 413. Each of the plurality of convex portions is a concentric convex portion centered on a central axis c2 of the lens portion 413 in a plan view. In a plan view, the central axis c2 of the lens portion 413 overlaps the center of the light-emitting device 1. The Fresnel lens can reduce the thickness of the light-emitting module 450.

Also in the light-emitting module 450 illustrated in FIG. 14A, similarly to the light-emitting module 400, the amount of change in the light distribution angle of the central light-emitting portion 40 caused by the lens 406 is larger than the amount of change in the light distribution angle of the outer light-emitting portion 10 caused by the lens 406.

The light-emitting module 460 according to the second modified example is different from the light-emitting module 400 in that a lens 407 including a lens portion 423 is provided. The lens 407 includes the lens portion 423 and the lens support portion 404 that supports the lens portion 423.

As illustrated in FIG. 14B, in the light-emitting module 460, a Fresnel lens having a flat light emission surface and a light incident surface provided with a central convex portion 415, a first convex portion 416, and a second convex portion 417 is used as the lens portion 423. Each of the first convex portion 416 and the second convex portion 417 is a concentric convex portion centered on a central axis c3 of the lens portion 423 in a plan view. That is, the lens portion 423 is a lens having rotational symmetry about the central axis c3. In a plan view, the central axis c3 of the lens portion 423 overlaps the center of the light-emitting device 1. In the light-emitting module 460, light emitted from the light-emitting device 1 is controlled on each surface of the central convex portion 415, the first convex portion 416 on the outer side of the central convex portion 415, and the second convex portion 417 on the outer side of the first convex portion 416, and desired irradiation light can be obtained by overlapping of the light controlled on each surface in an irradiation region. For example, in a case in which the light-emitting module 460 is used as a flash light source when an imaging device captures an image, an illuminance distribution having a substantially rectangular shape similar to a rectangular irradiation region can be obtained by light emitted from the lens portion 423.

The light-emitting module 470 according to the third modified example is different from the light-emitting module 400 in that a lens 408 including a lens portion 433 is provided. The lens 408 includes the lens portion 433 and the lens support portion 404 that supports the lens portion 433.

As illustrated in FIG. 14C, the lens portion 433 includes a convex portion 418 having a flat light emission surface and a curved light incident surface. The lens portion 433 has a concave center and two convex portions on outer sides of the center in cross section passing through a central axis c4 of the lens portion 433. The convex portion 418 is one concentric convex portion centered on the central axis c4 of the lens portion 433 in a plan view. That is, the lens portion 433 is a lens having rotational symmetry about the central axis c4. In a plan view, the central axis c4 of the lens portion 433 overlaps the central light-emitting portion 40. When the lens portion has a plate shape, light emitted from the light-emitting module can exhibit an illuminance distribution in which the illuminance at the center of light is higher than the illuminance on the periphery of the light can be obtained by. In the light-emitting module 470 including the lens portion 433 of the present modified example, light that exits from the lens portion 433 can exhibit an illuminance distribution in which an illuminance difference from the center to the periphery of light is reduced as compared with a case in which the lens portion has a plate shape. Accordingly, in the light-emitting module 470 of the present modified example, illuminance unevenness can be reduced in an illuminance distribution.

A light-emitting module 480 according to a fourth modified example of the light-emitting module 400 will be illustrated with reference to FIGS. 14D, 14E, 14F, and 14G. FIG. 14D is a schematic plan view of the light-emitting module 480 according to the fourth modified example. FIG. 14E is a schematic cross-sectional view taken along XIVE-XIVE in FIG. 14D. FIG. 14F is a schematic plan view of the light-emitting module according to the fourth modified example. FIG. 14G is a schematic cross-sectional view taken along XIVG-XIVG in FIG. 14F. Illustration of the lens 406 is omitted in FIG. 14D and FIG. 14F.

The light-emitting module 480 of the fourth modified example differs from the light-emitting module 450 of the first modified example mainly in further including at least one covering resin part 50.

As shown in FIG. 14D, the light-emitting module 480 includes a light-emitting device 1 having a rectangular shape with two longer lateral surfaces and two shorter lateral surfaces in a plan view. In the light-emitting device 1, the resin member 81 covers the first outer edge 101, the second outer edge 102, the third outer edge 103, and the fourth outer edge 104 of the light-emitting element 100. At least a portion of the resin member 81 constitutes the outer edges of the rectangular-shaped light-emitting device 1 in a plan view. In other words, in a plan view, the outer edges of the resin member 81 has a rectangular shape, and the resin member 81 has two longer lateral surfaces and two shorter lateral surfaces. Each of the four outer edges of the resin member 81 in a plan view is substantially parallel to a respective one of the first outer edge 101, the second outer edge 102, the third outer edge 103 and the fourth outer edge 104 of the light-emitting element 100.

As shown in FIGS. 14D and 14E, in the light-emitting module 480, the covering resin parts 50 are disposed in contact with the resin member 81 at locations on two opposite sides of the rectangular-shaped light-emitting device 1 in the first direction X in a plan view. In other words, the covering resin parts 50 are disposed directly on two lateral surfaces of the resin member 81 that are opposite to each other. In the example shown in FIG. 14D, the covering resin parts 50 are disposed in contact with two longer lateral surfaces of the light-emitting device 1. A coefficient of linear expansion of the at least one covering resin part 50 is smaller than a coefficient of linear expansion of the resin member 81. The covering resin part 50 contain a resin base material. The covering resin part 50 may further contain at least one of a light diffusive substance, a light absorbing substance, or a pigment. As the resin base material of the covering resin part 50, for example, the resin base material described above as the examples of the material of the phosphor layer 301 can be used. The light diffusion substance is, for example, titanium oxide or silicon oxide. The light absorption material is, for example, carbon black. The resin base material of the resin member 81 preferably contains at least one of silicone resin or silicone modified resin as the main component, and the resin base material of the covering resin part 50 preferably contains at least one of epoxy resin or epoxy modified resin as the main component. In the present embodiment, the resin base material of the resin member 81 is silicone resin, and the resin base material of the covering resin part 50 is epoxy resin. In the present embodiment, the covering resin part 50 contains a light diffusion substance. This allows the appearance color of the covering resin part 50 to be close to the appearance color of the resin member 81, so that the light-emitting module 480 can have good appearance in which difference between the color of the covering resin part 50 and the color of the resin member 81 is reduced. As long as the coefficient of linear expansion of the covering resin part 50 is smaller than the coefficient of linear expansion of the resin member 81, any appropriate composition of the resin base material, the light diffusion substance, the light absorbing substance, and the pigment may be used. When the covering resin part 50 having a coefficient of linear expansion smaller than the coefficient of linear expansion of the resin member 81 is disposed on the two opposite lateral surfaces of the rectangular resin member 81, thermal stress exerted to the light-emitting device 1 can be reduced. This will prevent damage to the light-emitting device 1 and damage to bonding parts such as solder that electrically connect the wiring portions of the light-emitting device 1 to the circuit unit of the mounting substrate 401. In the present embodiment, each of the two covering resin parts 50 are disposed in contact with a respective one of the two longer lateral surfaces of the light-emitting device 1, so that the contact area between the covering resin parts 50 and the resin member 81 can be increased compared to the case in which each of the two covering resin parts 50 are disposed in contact with a respective one of the two shorter lateral surfaces of the light-emitting device 1. In addition, in the present embodiment, each of the two covering resin parts 50 is disposed in contact with a respective one of the two lateral surfaces of the resin member 81 that are located on opposite sides of the resin member 81, but is not limited thereto. For example, the at least one covering resin part 50 is disposed in contact with the resin member 81 at locations corresponding to at least two lateral surfaces of the four lateral surfaces of the light-emitting device 1. A plurality of covering resin parts 50 may be separated from each other, or may be connected together near a corner portion of the light-emitting device 1 in a plan view of the light-emitting device 1. In the present embodiment, a lateral surface of the light-emitting device 1 includes a lateral surface of the resin member 81 and a lateral surface of the support member 200, but even if the light-emitting device does not include the support member 200, the thermal stress exerted on the light-emitting device can be reduced.

As shown in FIG. 14F and FIG. 14G, at least one recess 92 can be formed in the upper surface of the resin member 81. In the example shown in FIG. 14F, recesses 92 are formed to be parallel to the four lateral surfaces of the rectangular-shaped light-emitting device 1 in a plan view, and two of the recesses 92, each extending along the first direction X or the second direction Y, intersect with each other at each of the four corners of the light-emitting device 1. With the recess 92 formed in the upper surface of the resin member 81, even if the covering resin part 50 covers the upper surface of the light-emitting device 1 in the manufacturing process, the recess 92 can stem the flow of the covering resin part 50, inhibiting it from spreading to the upper surface of each wavelength conversion member 300. The width, shape, arrangement and number of recesses 92 in a plan view and the length of recess 92 in the third direction Z can be adjusted appropriately.

In the present embodiment, the covering resin part 50 is in contact with both a lateral surface of the light-emitting device 1 and the upper surface of the mounting substrate 401. With this structure, the contact area between the covering resin part 50 and the lateral surface of the light-emitting device 1 and the contact area between the covering resin part 50 and the upper surface of the mounting substrate 401 is increased, so that the mounting stability of the light-emitting device 1 can be improved. In the present embodiment, a lateral surface of the light-emitting device 1 includes a lateral surface of the resin member 81 and a lateral surface of the support member 200. Even in a case of a light-emitting device that does not include the support member 200, with the covering resin part 50 in contact with both a lateral surface of the light-emitting device and the upper surface of the mounting substrate 401, the mounting stability of the light-emitting device can be improved.

As shown in FIG. 14E, in the light-emitting module 480, at least a portion of the covering resin part 50 covers the lower surface of light-emitting device 1. The expression “the covering resin part 50 covers the lower surface of the light-emitting device 1” refers to that the covering resin part 50 is located between the lower surface of the light-emitting device 1 and the upper surface of the mounting substrate 401, and the covering resin part 50 is in contact with at least one of the lower surface of the light-emitting device 1 or the upper surface of the mounting substrate 401. With at least a portion of the covering resin part 50 covering the lower surface of the light-emitting device 1, at least one of the contact area between the covering resin part 50 and the lower surface of the light-emitting device 1 or the contact area between the covering resin part 50 and the upper surface of the mounting substrate 401 is increased, so that the mounting stability of light-emitting device 1 can be improved. In the present embodiment, the covering resin part 50 is in contact with both the lower surface of the light-emitting device 1 and the upper surface of the mounting substrate 401. Accordingly, mounting stability of the light-emitting device 1 can be further improved. In the present embodiment, the lower surface of the light-emitting device 1 includes the lower surface of the insulating base body 201 of the support member 200. Even in the case of a light-emitting device without the support member 200, with at least a portion of the covering resin part 50 covering the lower surface of the light-emitting device, the mounting stability of the light-emitting device can be improved.

As shown in FIG. 14D and FIG. 14E, in the light-emitting module 480, at least two electronic components 91 on the upper surface of the mounting substrate 401. The electronic components 91 include at least one of Zener diodes, thermistors, capacitors, light-receiving sensors, or the like. In the present embodiment, the light-emitting module 480 includes one electronic component 91 in the first direction X from the light-emitting device 1 and one electronic component 91 in a direction opposite to the direction X from the light-emitting device 1. Thus, the light-emitting device 1 is located between the at least two electronic components 91. In other words, the at least two electronic components 91 are arranged at opposite sides of light-emitting device 1 to face the lateral surfaces of the light-emitting device 1. The expression “the light-emitting device 1 is located between at least two electronic components 91” refers to that the light-emitting device 1 and the at least two electronic components 91 overlap at least partially in the first direction X or the second direction Y. Each of the at least one covering resin part 50 covers a corresponding one of the at least two electronic components 91. In the present embodiment, one covering resin part 50 covers one electronic component 91, and the other covering resin part 50 covers one electronic component 91. The at least one covering resin part 50 may cover at least one electronic component 91 or none of the electronic components 91.

### Method for Manufacturing Light-Emitting Device According to First Embodiment

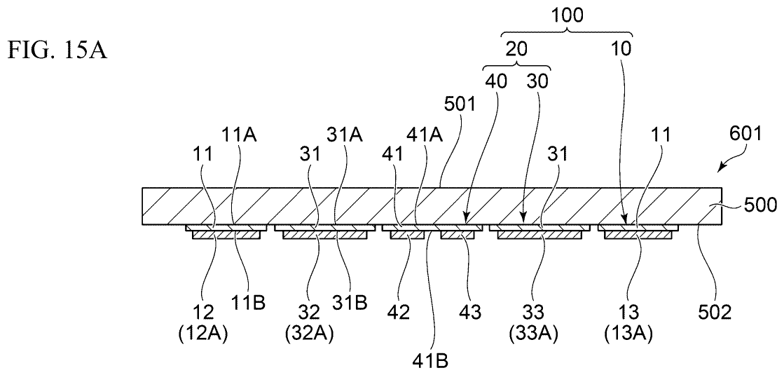

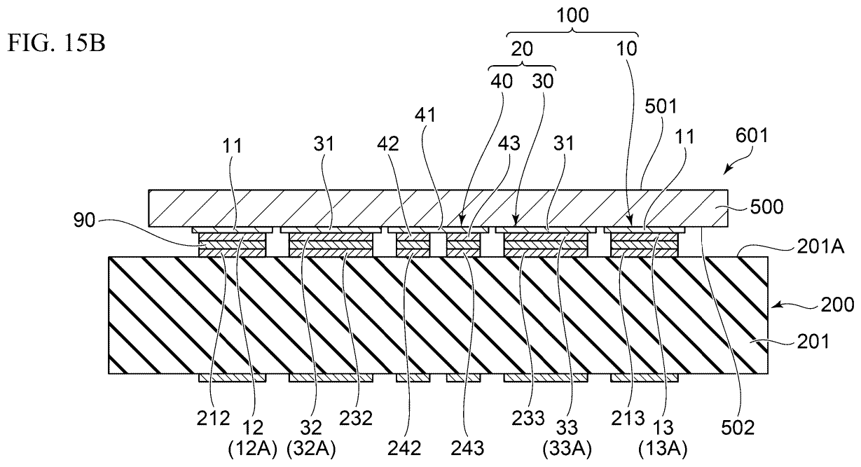

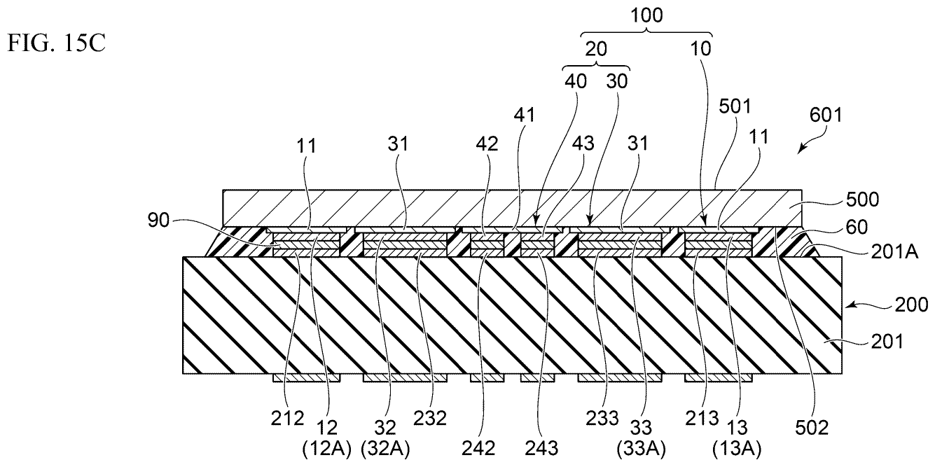

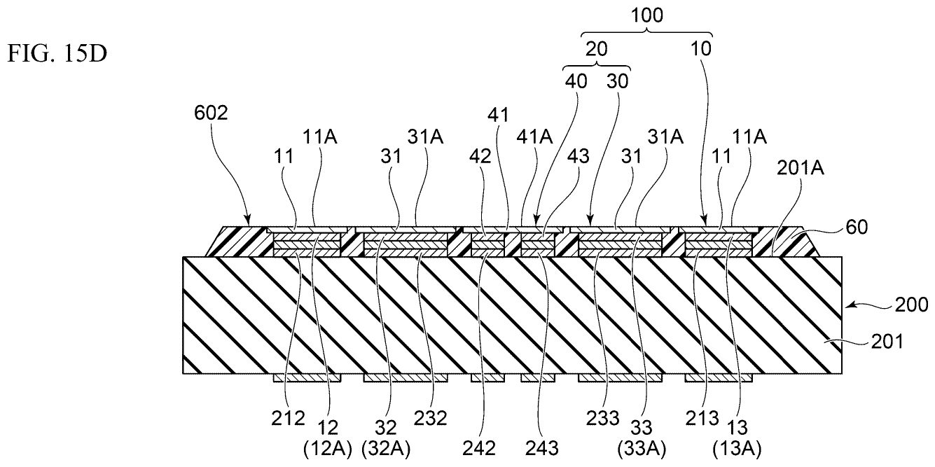

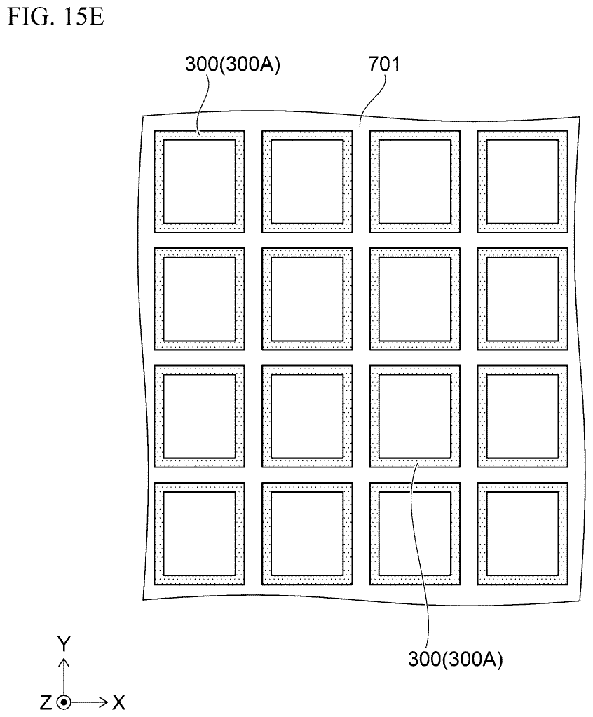

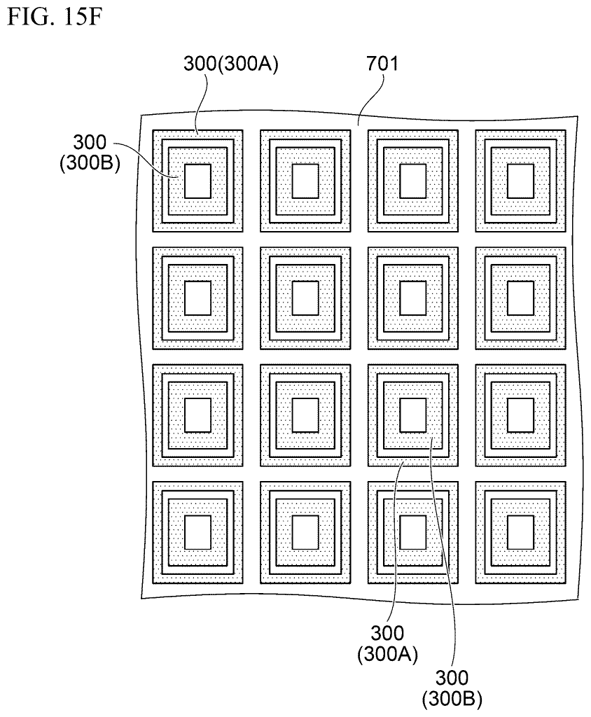

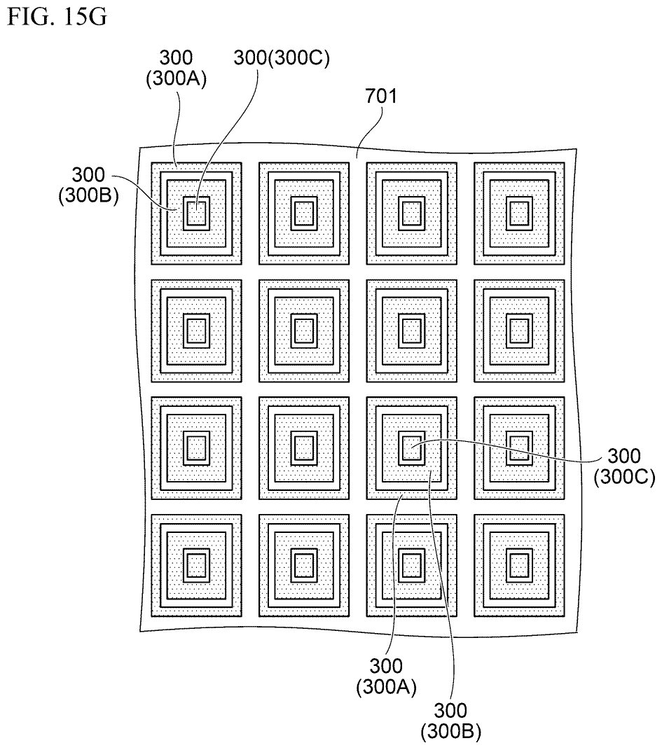

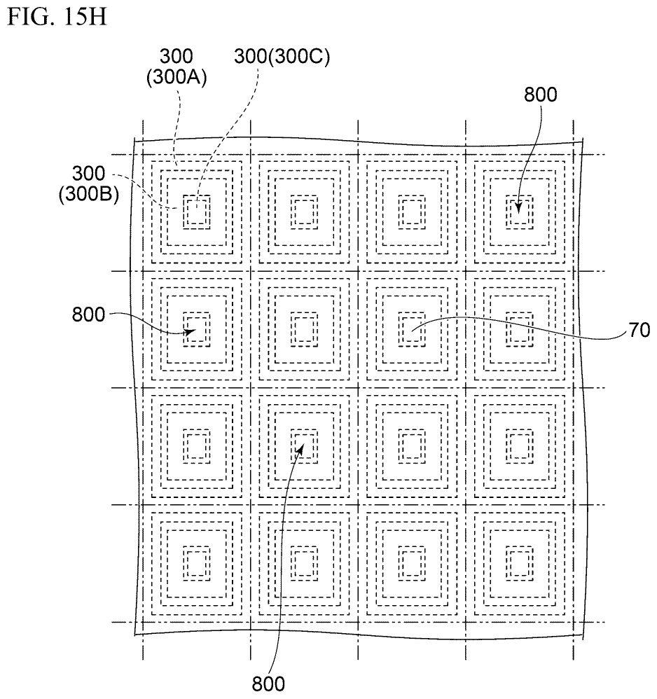

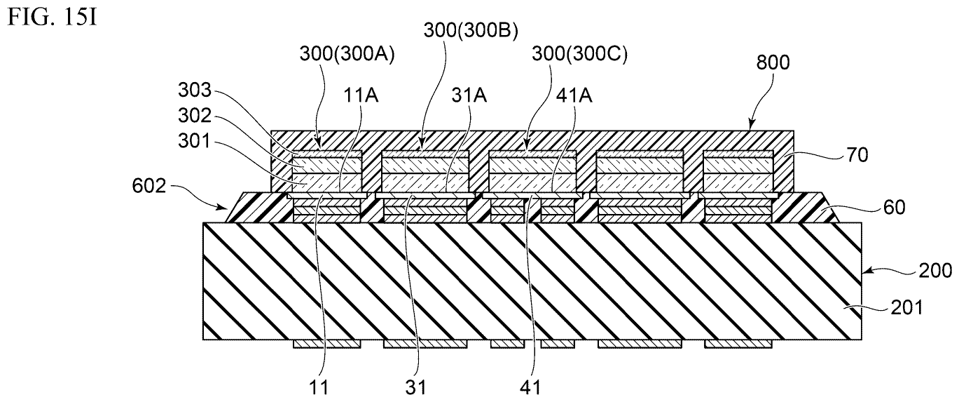

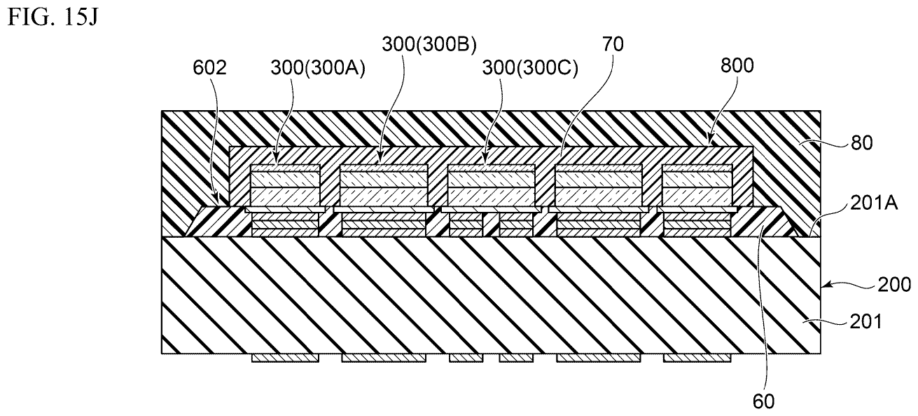

A method for manufacturing the light-emitting device 1 according to the first embodiment is described with reference to FIGS. 15A to 15J. The method for manufacturing the light-emitting device 1 includes a step of providing a structure including an element substrate and a light-emitting element having a rectangular shape in a plan view, a step of disposing the structure on a support member, and a step of separating the element substrate from the light-emitting element.

In the step of providing the structure including the element substrate and the light-emitting element having a rectangular shape in a plan view, a first structure 601 illustrated in FIG. 15A is provided. The first structure 601 includes an element substrate 500 and the light-emitting element 100 described above. The light-emitting element 100 has a rectangular shape having the first outer edge 101 and the second outer edge 102 extending in the first direction X and the third outer edge 103 and the fourth outer edge 104 extending in the second direction Y orthogonal to the first direction X in a plan view.

The light-emitting element 100 includes the inner light-emitting portion 20 and the outer light-emitting portion 10. The inner light-emitting portion 20 includes the inner semiconductor structure having the inner light-emitting surface and the inner electrode surface opposite to the inner light-emitting surface, and the positive and negative inner electrodes 32 and 33 disposed on the inner electrode surface. The outer light-emitting portion 10 includes the outer semiconductor structure 11 surrounding the entire periphery of the inner light-emitting portion 20 in a plan view and having the outer light-emitting surface 11A and the outer electrode surface 11B opposite to the outer light-emitting surface 11A, and the positive and negative outer electrodes 12 and 13 disposed on the outer electrode surface 11B. The outer electrodes 12 and 13 include the first outer electrode 12 and the second outer electrode 13. The first outer electrode 12 includes the first extending portion 12A extending along the first outer edge 101 and the second extending portion 12B extending along one of the third outer edge 103 and the fourth outer edge 104. The second outer electrode 13 includes the third extending portion 13A extending along the second outer edge 102 and the fourth extending portion 13B extending along the other of the third outer edge 103 and the fourth outer edge 104.

Through the method for manufacturing the light-emitting device 1 according to the first embodiment, for example, the light-emitting device 1 including the electrode pattern illustrated in FIGS. 3 and 6 can be manufactured.

The element substrate 500 includes a first surface 501 and a second surface 502 opposite to the first surface 501. As the element substrate 500, for example, a sapphire substrate can be used.

The light-emitting element 100 is disposed on the second surface 502 of the element substrate 500. The outer light-emitting surface 11A of the outer semiconductor structure 11, the frame-shaped inner light-emitting surface 31A of the frame-shaped inner semiconductor structure 31, and the central inner light-emitting surface 41A of the central inner semiconductor structure 41 face the second surface 502 of the element substrate 500.

In the step of providing the first structure 601, for example, after a semiconductor is grown on the second surface 502 of the element substrate 500 by a metal organic chemical vapor deposition (MOCVD) method, the semiconductor can be separated into the outer semiconductor structure 11, the frame-shaped inner semiconductor structure 31, and the central inner semiconductor structure 41 by etching such as reactive ion etching (RIE).

In the step of providing the first structure 601, the first outer electrode 12 and the second outer electrode 13 are formed on the outer electrode surface 11B of the outer semiconductor structure 11 opposite to the surface facing the second surface 502 by sputtering, for example. In addition, the first inner electrode 32 and the second inner electrode 33 are formed on the frame-shaped inner electrode surface 31B of the frame-shaped inner semiconductor structure 31 opposite to the surface facing the second surface 502. Moreover, the third inner electrode 42 and the fourth inner electrode 43 are formed on the central inner electrode surface 41B of the central inner semiconductor structure 41 opposite to the surface facing the second surface 502. The order of forming the electrodes is not particularly limited, and the electrodes may be formed at the same time.

In the present embodiment, the first structure 601 is a wafer in which a plurality of the light-emitting elements 100 are disposed on the element substrate 500. Alternatively, the first structure 601 may be a structure obtained by performing singulation of a wafer such that it includes at least one light-emitting element 100.

In the step of disposing the structure on the support member, as illustrated in FIG. 15B, the first structure 601 is disposed on the support member 200 such that the second surface 502 of the element substrate 500 and the first wiring surface 201A of the support member 200 described above face each other.

The respective electrodes of the light-emitting element 100 are bonded to the respective wiring portions on the first wiring surface 201A via the bonding members 90. In a state in which the first structure 601 is disposed on the support member 200, the distance between the second surface 502 of the element substrate 500 and the first wiring surface 201A of the support member 200 is, for example, in a range from 10 μm to 100 μm.

The present embodiment includes, after disposing the first structure 601 on the support member 200, a step of disposing the first resin member 60 between the support member 200 and the first structure 601 as illustrated in FIG. 15C.

In the step of disposing the first resin member 60, for example, the first structure 601 and the support member 200 are disposed in a mold, and a liquid resin material is supplied between the support member 200 and the first structure 601. For example, compression molding is used.

In the case of the light-emitting element 100 illustrated in FIG. 3, in the light-emitting element 100, the first gap g1 is located between the end portion of the first extending portion 12A and the end portion of the fourth extending portion 13B and the second gap g2 is located between the end portion of the second extending portion 12B and the end portion of the third extending portion 13A in a plan view. Therefore, between the support member 200 and the first structure 601, an uncured resin material can flow between the outer semiconductor structure 11 and the frame-shaped inner semiconductor structure 31, between the outer electrode 12 and the inner electrode 32, and between the outer electrode 13 and the inner electrode 33 through the first gap g1 and the second gap g2 illustrated in FIG. 3. Moreover, the resin material can flow between the frame-shaped inner semiconductor structure 31 and the central inner semiconductor structure 41 and between the inner electrode 32 and the inner electrode 42, and between the inner electrode 33 and the inner electrode 43 through the fifth gap g5 and the sixth gap g6.

On the other hand, in the case of the light-emitting element 100 illustrated in FIG. 6, in the light-emitting element 100, the third gap g3 is located between the end portion of the first extending portion 12A and the end portion of the second extending portion 12B and the fourth gap g4 is located between the end portion of the third extending portion 13A and the end portion of the fourth extending portion 13B in a plan view. The light-emitting element 100 illustrated in FIG. 6 further includes the seventh gap g7 and the eighth gap g8 as compared with the configuration illustrated in FIG. 3. Therefore, the resin material can more easily flow between the outer semiconductor structure 11 and the frame-shaped inner semiconductor structure 31, between the outer electrode 12 and the inner electrode 32, between the outer electrode 13 and the inner electrode 33, between the frame-shaped inner semiconductor structure 31 and the central inner semiconductor structure 41, between the inner electrode 32 and the inner electrode 42, and between the inner electrode 33 and the inner electrode 43.

After the resin material is supplied between the support member 200 and the first structure 601, for example, the resin material is cured by heating, and the first resin member 60 is disposed between the support member 200 and the first structure 601. The first resin member 60 covers the second surface 502 of the element substrate 500, the light-emitting element 100, the bonding member 90, and the wiring portion on the first wiring surface 201A. Thus, each semiconductor structure and each electrode of the light-emitting element 100 can be protected by the first resin member 60. The first resin member 60 may cover at least one lateral surface of the element substrate 500 as long as the first surface 501 of the element substrate 500 is exposed from the first resin member 60.

In the step of separating the element substrate from the light-emitting element, after disposing the first structure 601 on the support member 200, the element substrate 500 is separated from the light-emitting element 100. In the present embodiment, after the step of disposing the first resin member 60 described above, the element substrate 500 is separated from the light-emitting element 100. By separating the light-emitting element 100 and the element substrate 500, that is, by removing the element substrate 500 from the first structure 601, a light source unit 602 is formed on the support member 200 as illustrated in FIG. 15D. In the light source unit 602, the outer light-emitting surface 11A of the outer semiconductor structure 11, the frame-shaped inner light-emitting surface 31A of the frame-shaped inner semiconductor structure 31, and the central inner light-emitting surface 41A of the central inner semiconductor structure 41 are exposed from the first resin member 60.

For example, the element substrate 500 is a sapphire substrate, and the semiconductor structures (the outer semiconductor structure 11, the frame-shaped inner semiconductor structure 31, and the central inner semiconductor structure 41) contain gallium nitride (GaN). In this case, the semiconductor structure and the element substrate 500 can be separated by a laser lift-off method.

In the laser lift-off method, laser light is emitted from the first surface 501 side of the element substrate 500 toward the outer light-emitting surface 11A of the outer semiconductor structure 11, the frame-shaped inner light-emitting surface 31A of the frame-shaped inner semiconductor structure 31, and the central inner light-emitting surface 41A of the central inner semiconductor structure 41. The laser light passes through the element substrate 500 and has a wavelength in an absorption region with respect to each semiconductor structure. The laser light is light having a light emission peak wavelength in a range of 190 nm to 380 nm, for example. Gallium nitride absorbs the energy of the laser light and is thermally decomposed. By the emission of the laser light, gallium nitride is decomposed into nitrogen and gallium on the light-emitting surface of each semiconductor structure, and the element substrate 500 is removed off from each semiconductor structure. In addition, the first resin member 60 absorbs the energy of the laser light.

In the step of separating the element substrate 500 from the light-emitting element 100 by the laser lift-off method, each semiconductor structure is supported on the support member 200 in a state in which the semiconductor structure is covered with the first resin member 60 except for the light-emitting surface. The first resin member 60 can absorb an impact caused by nitrogen gas generated during thermal decomposition of gallium nitride. Thus, compared with a case in which the first resin member 60 is not provided, the stress exerted to the semiconductor structure can be reduced and unintended cracking of the semiconductor structure can be reduced.

Due to an impact at the time of the laser lift-off, a portion having a relatively low strength in the semiconductor structure is likely to be damaged, for example, partially recessed or cracked. For example, the strength of a portion of the semiconductor structure where no electrode is disposed is likely to be weak.

According to the present embodiment, as described above with reference to FIG. 3 or 6, the outer electrodes 12 and 13 extend along the first outer edge 101, the second outer edge 102, the third outer edge 103, and the fourth outer edge 104 of the light-emitting element 100 to increase the area of the outer electrodes 12 and 13, so that partial damage to the outer semiconductor structure 11 due to an impact at the time of laser lift-off can be reduced. This makes it possible to improve the light emission characteristics of the outer light-emitting portion 10.

Similarly, the inner electrodes 32 and 33 extend along the first outer edge 101, the second outer edge 102, the third outer edge 103, and the fourth outer edge 104 to increase the area of the inner electrodes 32 and 33, so that partial damage to the frame-shaped inner semiconductor structure 31 due to an impact at the time of laser lift-off can be reduced. This makes it possible to improve the light emission characteristics of the frame-shaped inner light-emitting portion 30.

As illustrated in FIGS. 3 and 6, in the present embodiment, the positive and negative inner electrodes 32, 33, 42, and 43 are located on the virtual line L connecting the first gap g1 and the second gap g2 in a plan view. That is, the outer electrode and the inner electrode overlap each other in the direction of the virtual line L. Thus, the outer semiconductor structure 11, the frame-shaped inner semiconductor structure 31, and the central inner semiconductor structure 41 can be reinforced, and damage to each of them due to an impact at the time of laser lift-off can be reduced.

When the outer semiconductor structure 11 having a frame shape in a plan view receives an impact at the time of laser lift-off, stress is likely to be concentrated on the corner portion thereof. In the configuration illustrated in FIG. 3, at the corner portion where the first outer edge 101 and the third outer edge 103 intersect with each other, the first extending portion 12A and the second extending portion 12B of the first outer electrode 12 are continuous with each other forming the corner portion. In addition, at the corner portion where the second outer edge 102 and the fourth outer edge 104 intersect with each other, the third extending portion 13A and the fourth extending portion 13B of the second outer electrode 13 are continuous with each other forming the corner portion. This makes it possible to reduce damage to the corner portions of the outer semiconductor structure 11 at the time of laser lift-off.

In the configuration illustrated in FIG. 3, the fifth extending portion 32A and the sixth extending portion 32B of the first inner electrode 32 are continuous with each other forming a corner portion, and the seventh extending portion 33A and the eighth extending portion 33B of the second inner electrode 33 are continuous with each other forming a corner portion. This makes it possible to reduce damage to the corner portions of the frame-shaped inner semiconductor structure 31 at the time of laser lift-off.

For the outer electrode and the inner electrode, the number and positions of the gaps are not limited to the examples illustrated in FIGS. 3 and 6. For two or more gaps, the distance between the gaps is not limited to the examples illustrated in FIGS. 3 and 6. The number and positions of the gaps and the distance between the gaps may be appropriately adjusted in consideration of a region or the like of the frame-shaped inner semiconductor structure 31 to be reinforced at the time of laser lift-off.

The method for manufacturing the light-emitting device 1 includes a step of disposing the wavelength conversion member 300 on the light source unit 602 as illustrated in FIG. 15I. The step of disposing the wavelength conversion member 300 on the light source unit 602 can include, for example, a step of providing a wavelength conversion structure 800 in which the wavelength conversion members 300A, 300B, and 300C described above are integrally held by the second resin member 70, and a step of disposing the wavelength conversion structure 800 on the light source unit 602.

Subsequently, a step of providing the wavelength conversion structure including the wavelength conversion member 300 is described with reference to FIGS. 15E to 15H.

First, the wavelength conversion members 300A, 300B, and 300C are provided. The outer wavelength conversion member 300A can be formed in a frame shape in a plan view by, for example, punching out a central portion of a wavelength conversion member having a rectangular shape in a plan view with a punch. Similarly, the inner wavelength conversion member 300B can be formed in a frame shape in a plan view by punching out a central portion of a wavelength conversion member having a rectangular shape with a punch. The central wavelength conversion member 300C having a rectangular shape in a plan view can be formed by dicing a sheet-like wavelength conversion member by, for example, blade processing or laser processing.

As illustrated in FIG. 15E, a plurality of outer wavelength conversion members 300A each having a frame shape in a plan view are arranged in a matrix on a sheet 701.

After the plurality of outer wavelength conversion members 300A are disposed on the sheet 701, a plurality of inner wavelength conversion members 300B each having a frame shape in a plan view are disposed on the sheet 701 as illustrated in FIG. 15F. A single inner wavelength conversion member 300B is disposed on an inner side of a single outer wavelength conversion member 300A. At this time, the outer wavelength conversion member 300A and the inner wavelength conversion member 300B are spaced apart from each other.

After the plurality of inner wavelength conversion members 300B are disposed on the sheet 701, a plurality of central wavelength conversion members 300C each having a rectangular shape in a plan view are disposed on the sheet 701 as illustrated in FIG. 15G. A single central wavelength conversion member 300C is disposed inward of a single inner wavelength conversion member 300B. At this time, the inner wavelength conversion member 300B and the central wavelength conversion member 300C are spaced apart from each other.

After the wavelength conversion members 300A, 300B, and 300C are disposed on the sheet 701, the second resin member 70 being a liquid resin material is applied onto the sheet 701 by printing so as to cover the upper surfaces and the lateral surfaces of the wavelength conversion members 300A, 300B, and 300C as illustrated in FIG. 15H. Subsequently, the second resin member 70 is cured by heating.

After the second resin member 70 is cured, the second resin member 70 and the sheet 701 located in a region between adjacent outer wavelength conversion members 300A are cut as indicated by the two-dot chain line in FIG. 15H. Thus, a plurality of wavelength conversion structures 800 each including the wavelength conversion member 300 are obtained by singulation.

As illustrated in FIG. 15I, the wavelength conversion structure 800 is disposed on the light source unit 602. At this time, the outer wavelength conversion member 300A overlaps the outer light-emitting surface 11A, the inner wavelength conversion member 300B overlaps the frame-shaped inner light-emitting surface 31A, and the central wavelength conversion member 300C overlaps the central inner light-emitting surface 41A. By disposing the wavelength conversion structure 800 on the light source unit 602 in this manner, the second resin member 70 is disposed on the first resin member 60.

The wavelength conversion structure 800 is adhered to the light source unit 602 via an adhesive layer. Alternatively, the wavelength conversion structure 800 may be directly bonded to the light source unit 602.

The method for manufacturing the light-emitting device 1 includes, after disposing the wavelength conversion structure 800 on the light source unit 602, a step of disposing the third resin member 80 on the support member 200. In the step of disposing the third resin member 80 on the support member 200, as illustrated in FIG. 15J, the upper surface and lateral surfaces of the wavelength conversion structure 800 and the upper surface of the light source unit 602 (in FIG. 15J, a part of the upper surface of the first resin member 60, a part of inclined lateral surfaces, and a part of the first wiring surface 201A) are covered with the third resin member 80.

The method for manufacturing the light-emitting device 1 includes, after disposing the third resin member 80 on the support member 200, a step of removing a part of the upper surface side of the third resin member 80 and a part of the upper surface side of the second resin member 70. Thus, as illustrated in FIG. 2, the upper surface of the outer wavelength conversion member 300A, the upper surface of the inner wavelength conversion member 300B, and the upper surface of the central wavelength conversion member 300C are exposed from the third resin member 80 and the second resin member 70. For example, a part of the upper surface side of the third resin member 80 and a part of the upper surface side of the second resin member 70 can be removed by grinding.

The light-emitting device 1 illustrated in FIG. 2 can be obtained through the steps describe above.

Method for Manufacturing Light-emitting Device according to Second Embodiment

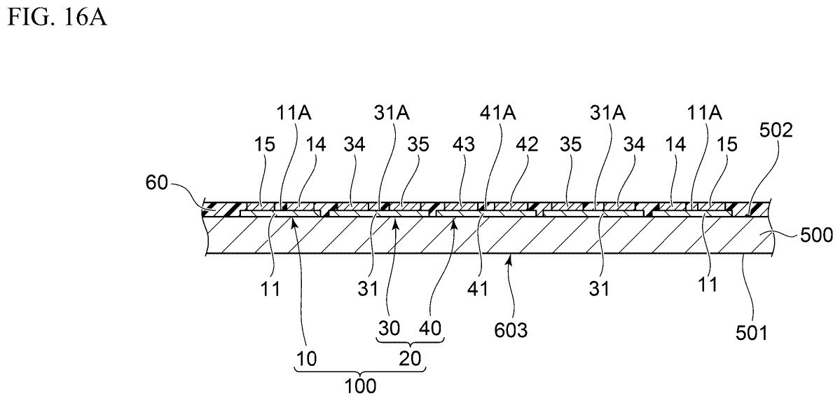

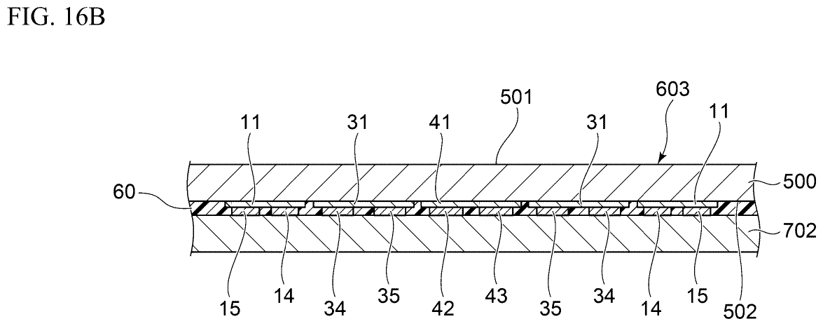

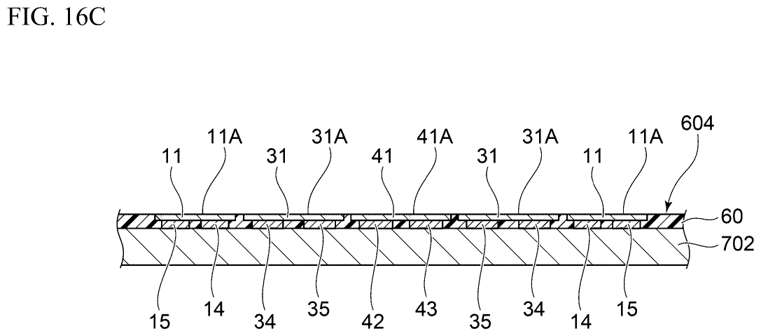

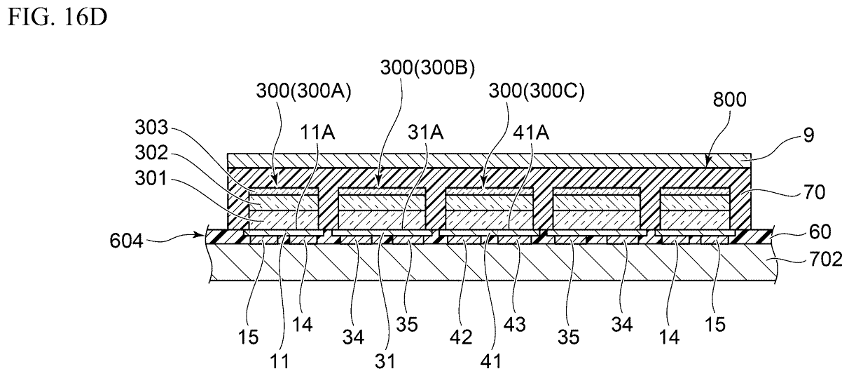

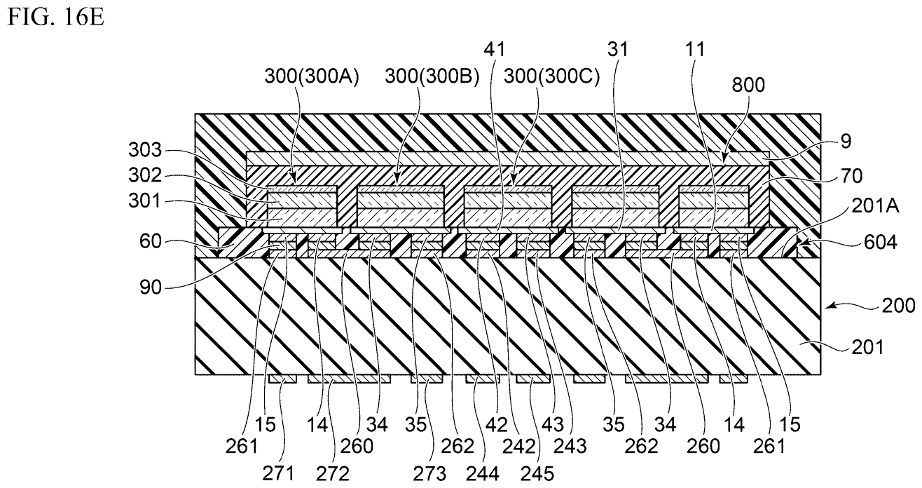

A method for manufacturing the light-emitting device 2 according to the second embodiment will be described below with reference to FIGS. 16A to 16E. The method for manufacturing the light-emitting device 2 according to the second embodiment is different from the method for manufacturing the light-emitting device 1 according to the first embodiment mainly in the order of the step of disposing the structure on the support member and the step of separating the element substrate from the light-emitting element.

By the method for manufacturing the light-emitting device 2 according to the second embodiment, for example, the light-emitting device 2 including any one of the electrode patterns illustrated in FIGS. 3, 6, and 10 can be manufactured.

The method for manufacturing the light-emitting device 2 includes a step of providing a second structure 603 illustrated in FIG. 16A. The second structure 603 includes the element substrate 500 and the light-emitting element 100 disposed on the second surface 502 of the element substrate 500. The light-emitting element 100 is a light-emitting element according to the second embodiment, and includes the first outer electrode 14, the second outer electrode 15, the first inner electrode 34, the second inner electrode 35, the third inner electrode 42, and the fourth inner electrode 43 illustrated in FIG. 10. The second structure 603 is a wafer in which a plurality of the light-emitting elements 100 are disposed on the element substrate 500.

The second structure 603 further includes the first resin member 60 disposed on the second surface 502 of the element substrate 500 and covering the light-emitting element 100. The surfaces of the first outer electrode 14, the second outer electrode 15, the first inner electrode 34, the second inner electrode 35, the third inner electrode 42, and the fourth inner electrode 43 opposite to the semiconductor structure are exposed from the first resin member 60.

In the step of providing the second structure 603, the first resin member 60 is formed by supplying the first resin member 60 in a liquid state onto the second surface 502 of the element substrate 500 so as to cover the light-emitting element 100 and then curing the liquid first resin member 60 by heating. Subsequently, the cured first resin member 60 is ground such that the surface of each electrode of the light-emitting element 100 opposite to the semiconductor structure exposes from the first resin member 60. Subsequently, the element substrate 500 and the first resin member 60 are cut such that one light-emitting element 100 includes one outer semiconductor structure 11, one frame-shaped inner semiconductor structure 31, and one central inner semiconductor structure 41. Thus, the first resin member 60 can be formed between the outer semiconductor structure 11 and the frame-shaped inner semiconductor structure 31, between the frame-shaped inner semiconductor structure 31 and the central inner semiconductor structure 41, and between the electrodes.

The method for manufacturing the light-emitting device 2 includes a step of disposing the second structure 603 on the support member 702 as illustrated in FIG. 16B. The support member 702 in the present embodiment is a holding member for temporarily holding the light-emitting element 100 in the manufacturing process. The support member 702 (hereinafter, also referred to as a holding member 702) is, for example, a sheet. The second structure 603 is disposed on the support member 702 (holding member 702) such that the second surface 502 of the element substrate 500 faces the support member 702 (holding member 702).

The method for manufacturing the light-emitting device 2 includes, after disposing the second structure 603 on the support member 702 (holding member 702), a step of separating the element substrate 500 from the light-emitting element 100. By separating the light-emitting element 100 and the element substrate 500 from each other, a light source unit 604 including the second structure 603 is formed on the holding member 702 as illustrated in FIG. 16C. In the present embodiment, the holding member 702 is in a state of a wafer including a plurality of the light source units 604 on the upper surface thereof. In the light source unit 604, the outer light-emitting surface 11A of the outer semiconductor structure 11, the frame-shaped inner light-emitting surface 31A of the frame-shaped inner semiconductor structure 31, and the central inner light-emitting surface 41A of the central inner semiconductor structure 41 are exposed from the first resin member 60. As in the first embodiment, the element substrate 500 can be separated from the light-emitting element 100 by the laser lift-off method.

According to the present embodiment, when the second structure 603 includes any one of the electrode patterns illustrated in FIGS. 3, 6, and 10, the outer electrodes 12 and 13 and the inner electrodes 32 and 33 are extended along the first outer edge 101, the second outer edge 102, the third outer edge 103, and the fourth outer edge 104 of the light-emitting element 100 to increase the areas of the outer electrodes 12 and 13 and the inner electrodes 32 and 33, thereby reducing partial damage to the outer semiconductor structure 11 and the frame-shaped inner semiconductor structure 31 due to an impact at the time of laser lift-off. Thus, the light emission characteristics of the outer light-emitting portion 10 and the inner light-emitting portion 20 can be improved.

According to the present embodiment, when the second structure 603 includes the electrode pattern illustrated in FIG. 10, each of the outer electrodes 14 and 15 and the inner electrodes 34 and 35 has a rectangular frame shape that is continuous along the first outer edge 101, the second outer edge 102, the third outer edge 103, and the fourth outer edge 104. This makes it possible to increase the strength of the outer semiconductor structure 11 and the frame-shaped inner semiconductor structure 31 in the entire circumferential direction (including the corner portions) along the first outer edge 101, the second outer edge 102, the third outer edge 103, and the fourth outer edge 104, and to reduce partial damage to the semiconductor structures due to an impact at the time of laser lift-off. Thus, the light emission characteristics of the outer light-emitting portion 10 and the inner light-emitting portion 20 can be improved.

In the method for manufacturing the light-emitting device 2, after the light-emitting element 100 and the element substrate 500 are separated from each other, a single wavelength conversion structure 800 is disposed on each light source unit 604 including a single second structure 603. As the wavelength conversion structure 800, a wavelength conversion structure provided separately in the step of providing the wavelength conversion structure (see FIGS. 15E to 15H) is used. In the present embodiment, a protective member 9 is provided on the upper surface of the wavelength conversion structure 800 as illustrated in FIG. 16D such that the wavelength conversion structure 800 is easily transferred by a jig or damage to the wavelength conversion structure 800 is reduced when the wavelength conversion structure 800 is transferred onto the light source unit 604 by the jig. The protective member 9 includes glass or resin, for example, and is disposed on the upper surface of the wavelength conversion structure 800 via an adhesive member. As long as the jig can transfer the wavelength conversion structure 800, the protective member 9 need not be provided on the upper surface of the wavelength conversion structure 800.

The method for manufacturing the light-emitting device 2 includes, after disposing a single wavelength conversion structure 800 on each light source unit 604 including a single second structure 603, a step of disposing a single light source unit 604 including a single second structure 603 on the support member 200. In this step, the bonding member 90 is disposed on the support member 200, and the electrodes of the light-emitting element 100 are bonded to respective corresponding ones of the wiring portions on the first wiring surface 201A via the bonding member 90. In the present embodiment, a plurality of sets each including one light source unit 604 and one wavelength conversion structure 800 are disposed on one common support member 200. Alternatively, a plurality of the support members 200 may be provided, and one set of the light source unit 604 and the wavelength conversion structure 800 may be disposed on each of the plurality of support members 200.

The method for manufacturing the light-emitting device 2 includes, after bonding the electrodes of the light-emitting element 100 to corresponding ones of the wiring portions on the first wiring surface 201A, a step of disposing the third resin member 80 on the support member 200. In the step of disposing the third resin member 80 on the support member 200, as illustrated in FIG. 16E, the upper surface and lateral surfaces of the protective member 9, the lateral surfaces of the wavelength conversion structure 800, and the upper surface of the light source unit 604 (in FIG. 16E, a part of the upper surface of the first resin member 60, a part of the lateral surfaces, and a part of the first wiring surface 201A) are covered with the third resin member 80. The lateral surface of the first resin member 60 may be exposed from the lateral surface of the third resin member 80. In this case, the first resin member 60 covers the first wiring surface 201A, and thus the third resin member 80 need not be in contact with the first wiring surface 201A.

The method for manufacturing the light-emitting device 2 includes, after disposing the third resin member 80 on the support member 200, a step of removing a part of the upper surface side of the third resin member 80 and a part of the upper surface side of the second resin member 70. In the present embodiment, the protective member 9 is also removed in this step. Thus, as illustrated in FIG. 2 or FIG. 11, the upper surface of the outer wavelength conversion member 300A, the upper surface of the inner wavelength conversion member 300B, and the upper surface of the central wavelength conversion member 300C are exposed from the third resin member 80 and the second resin member 70. For example, a part of the upper surface side of the third resin member 80, the protective member 9, and a part of the upper surface side of the second resin member 70 can be removed by grinding. Note that when at least one of the support member 200 and the third resin member 80 is continuous between adjacent second structures 603 (in other words, the light source units 604), cutting is performed by dicing or the like between the adjacent second structures 603. Thus, a plurality of light-emitting devices 2 are obtained by singulation.

The light-emitting device 2 illustrated in FIG. 2 or FIG. 11 can be obtained through the steps describe above.

According to the light-emitting device, the light-emitting module, and the method for manufacturing a light-emitting device of the present disclosure, the area of a semiconductor structure and the area of an electrode can be increased, and the light-emitting device, the light-emitting module, and the method for manufacturing a light-emitting device can be suitably used for a flash light source of an imaging device such as a camera, lighting, an in-vehicle headlight, and the like. However, the light-emitting device, the light-emitting module, and the method for manufacturing a light-emitting device of the present disclosure are not limited to these uses.

Certain embodiments of the present invention have been described above with reference to specific examples. However, the present invention is not limited to these specific examples. All aspects that can be practiced by a person skilled in the art changing the design as appropriate based on the above-described embodiments of the present invention are also included in the scope of the present invention, as long as they encompass the spirit of the present invention. In addition, in the spirit of the present invention, a person skilled in the art can conceive of various modified examples and modifications, and those modified examples and modifications will also fall within the scope of the present invention.

What is claimed is:

1. A light-emitting device comprising:
a support member; and
a light-emitting element disposed on the support member, the light-emitting element having a rectangular shape in a plan view and including, in the plan view, a first outer edge and a second outer edge each extending in a first direction, and a third outer edge and a fourth outer edge each extending in a second direction orthogonal to the first direction, the light-emitting element comprising:
an inner light-emitting portion comprising:
an inner semiconductor structure having an inner light-emitting surface, and an inner electrode surface located on a side opposite the inner light-emitting surface, and
first and second inner electrodes disposed on the inner electrode surface; and
an outer light-emitting portion surrounding an entire periphery of the inner light-emitting portion in the plan view and comprising:
an outer semiconductor structure having an outer light-emitting surface, and an outer electrode surface located on a side opposite the outer light-emitting surface, and
first and second outer electrodes disposed on the outer electrode surface, wherein:
the first outer electrode comprises:
a first extending portion extending along the first outer edge, and
a second extending portion extending along one of the third outer edge and the fourth outer edge, and
the second outer electrode comprises:
a third extending portion extending along the second outer edge, and
a fourth extending portion extending along the other of the third outer edge and the fourth outer edge, wherein:
an outermost surface of the light-emitting element includes the inner light-emitting surface of the inner semiconductor structure and the outer light-emitting surface of the outer semiconductor structure,
in the plan view, a first gap is located between an end portion of the first extending portion and an end portion of the fourth extending portion, and a second gap is located between an end portion of the second extending portion and an end portion of the third extending portion.

2. The light-emitting device according to claim 1, wherein the first extending portion and the second extending portion are continuous with each other, and the third extending portion and the fourth extending portion are continuous with each other.

3. The light-emitting device according to claim 1, wherein in the plan view, a third gap is located between the end portion of the first extending portion and the end portion of the second extending portion, and a fourth gap is located between the end portion of the third extending portion and the end portion of the fourth extending portion.

4. The light-emitting device according to claim 1, wherein the first and second inner electrodes are located on a virtual line connecting the first gap and the second gap in the plan view.

5. The light-emitting device according to claim 1, wherein:
the inner light-emitting portion comprises a frame-shaped light-emitting portion along the first outer edge, the second outer edge, the third outer edge, and the fourth outer edge in the plan view,
the first inner electrode and the second inner electrode are disposed on an inner electrode surface of the frame-shaped light-emitting portion,
the first inner electrode comprises a fifth extending portion extending along the first extending portion, and a sixth extending portion extending along the second extending portion,
the second inner electrode comprises a seventh extending portion extending along the third extending portion, and an eighth extending portion extending along the fourth extending portion,
the first inner electrode and the first outer electrode are adjacent to each other and have a same polarity, and
the support member comprises a common wiring portion bonded to the first inner electrode and the first outer electrode of the light-emitting element.

6. The light-emitting device according to claim 1, wherein a ratio of a total length of the first and second outer electrodes in directions along the first outer edge, the second outer edge, the third outer edge, and the fourth outer edge to a total length of the outer electrode surface in the directions along the first outer edge, the second outer edge, the third outer edge, and the fourth outer edge is 0.8 or more.

7. A light-emitting device comprising:
a support member; and
a light-emitting element disposed on the support member, the light-emitting element having a rectangular shape in a plan view and including, in the plan view, a first outer edge and a second outer edge each extending in a first direction, and a third outer edge and a fourth outer edge each extending in a second direction orthogonal to the first direction, the light-emitting element comprising:
an inner light-emitting portion comprising:
an inner semiconductor structure having an inner light-emitting surface, and an inner electrode surface located on a side opposite the inner light-emitting surface, and
first and second inner electrodes disposed on the inner electrode surface, wherein:
the first inner electrode is continuous along the first outer edge, the second outer edge, the third outer edge, and the fourth outer edge, and
the second inner electrode is continuous along the first outer edge, the second outer edge, the third outer edge, and the fourth outer edge, and
an outer light-emitting portion surrounding an entire periphery of the inner light-emitting portion in the plan view and comprising:
an outer semiconductor structure having an outer light-emitting surface, and an outer electrode surface located on a side opposite the outer light-emitting surface, and
first and second outer electrodes disposed on the outer electrode surface, wherein:
the first outer electrode is continuous along the first outer edge, the second outer edge, the third outer edge, and the fourth outer edge, and
the second outer electrode is continuous along the first outer edge, the second outer edge, the third outer edge, and the fourth outer edge, wherein:
an outermost surface of the light-emitting element includes the inner light-emitting surface of the inner semiconductor structure and the outer light-emitting surface of the outer semiconductor structure,
in the plan view, the first outer electrode and the first inner electrode are disposed between the second outer electrode and the second inner electrode, and
the support member comprises a common wiring portion bonded to the first outer electrode and the first inner electrode.

8. The light-emitting device according to claim 1, further comprising a wavelength conversion member disposed above the inner light-emitting surface and the outer light-emitting surface.

9. A light-emitting module comprising:
the light-emitting device according to claim 1 in which the inner light-emitting portion comprises a central light-emitting portion having a rectangular shape, located at a center of the inner light-emitting portion, and configured to emit light to a central region in an irradiation region; and
a lens disposed above the inner light-emitting surface and the outer light-emitting surface of the light-emitting device, wherein:
an amount of change in a light distribution angle of the central light-emitting portion caused by the lens is larger than an amount of change in a light distribution angle of the outer light-emitting portion caused by the lens.

10. A light-emitting module comprising:
the light-emitting device according to claim 7 in which the inner light-emitting portion comprises a central light-emitting portion having a rectangular shape, located at a center of the inner light-emitting portion, and configured to emit light to a central region in an irradiation region; and
a lens disposed above the inner light-emitting surface and the outer light-emitting surface of the light-emitting device, wherein:
an amount of change in a light distribution angle of the central light-emitting portion caused by the lens is larger than an amount of change in a light distribution angle of the outer light-emitting portion caused by the lens.

11. A method for manufacturing a light-emitting device, the method comprising:
providing a structure comprising:
an element substrate having a first surface and a second surface located at a side opposite the first surface, and
a light-emitting element having a rectangular shape, disposed on the second surface of the element substrate, and comprising, in a plan view, a first outer edge and a second outer edge each extending in a first direction, and a third outer edge and a fourth outer edge each extending in a second direction orthogonal to the first direction,
disposing the structure on a support member such that the second surface of the element substrate faces the support member; and
after the disposing of the structure on the support member, separating the element substrate from the light-emitting element, wherein:
the light-emitting element comprises:
an inner light-emitting portion comprising
an inner semiconductor structure having an inner light-emitting surface, and an inner electrode surface located at a side opposite the inner light-emitting surface, and
first and second inner electrodes disposed on the inner electrode surface; and
an outer light-emitting portion surrounding an entire periphery of the inner light-emitting portion in the plan view and comprising:
an outer semiconductor structure having an outer light-emitting surface, and an outer electrode surface located at a side opposite the outer light-emitting surface, and
first and second outer electrodes disposed on the outer electrode surface, wherein:
the first outer electrode comprises a first extending portion extending along the first outer edge, and a second extending portion extending along one of the third outer edge and the fourth outer edge; and
the second outer electrode comprises a third extending portion extending along the second outer edge, and a fourth extending portion extending along the other of the third outer edge and the fourth outer edge.

12. The method for manufacturing a light-emitting device, according to claim 11, further comprising:
after the disposing of the structure on the support member, disposing a resin member between the support member and the structure, wherein:
in the plan view, a first gap is located between an end portion of the first extending portion and an end portion of the fourth extending portion, and a second gap is located between an end portion of the second extending portion and an end portion of the third extending portion.

13. The method for manufacturing a light-emitting device, according to claim 12, wherein, in the plan view, a third gap is located between the end portion of the first extending portion and the end portion of the second extending portion, and a fourth gap is located between the end portion of the third extending portion and the end portion of the fourth extending portion.

14. The light-emitting device according to claim 1, further comprising a resin member covering the first outer edge, the second outer edge, the third outer edge, and the fourth outer edge of the light-emitting element, wherein at least a portion of the resin member constitutes outer edges of the light-emitting device having a rectangular shape in the plan view.

15. The light-emitting device according to claim 7, further comprising a resin member covering the first outer edge, the second outer edge, the third outer edge, and the fourth outer edge of the light-emitting element, wherein at least a portion of the resin member constitutes outer edges of the light-emitting device having a rectangular shape in the plan view.

16. A light emitting module comprising:
the light-emitting device according to claim 14;
a mounting substrate having an upper surface on which the light emitting device is disposed; and
at least one covering resin part disposed in contact with two lateral surfaces of the resin member that are located on opposite sides of the resin member,
wherein a coefficient of linear expansion of the covering resin part is less than a coefficient of linear expansion of the resin member.

17. A light emitting module comprising:
the light-emitting device according to claim 15;
a mounting substrate having an upper surface on which the light emitting device is disposed; and
at least one covering resin part disposed in contact with two lateral surfaces of the resin member that are located on opposite sides of the resin member,
wherein a coefficient of linear expansion of the covering resin part is less than a coefficient of linear expansion of the resin member.

18. The light emitting module according to claim 16, further comprising:
at least two electronic components disposed on the upper surface of the mounting substrate, wherein:
the light-emitting device is located between the at least two electronic components, and
each of the at least two electronic components is covered by a corresponding one of the at least one covering resin part.

19. The light emitting module according to claim 16, wherein at least a portion of the at least one covering resin part covers a lower surface of light emitting device.

20. The light emitting module according to claim 16, wherein:
the resin member has two longer lateral surfaces and two shorter lateral surfaces, and
the at least one covering resin part is disposed in contact with at least the two longer lateral surfaces.
